(19) United States
(12) Patent Application Publication
(10) Pub. No.: US 2025/0176174 A1
(43) Pub. Date: May 29, 2025

(54) SEMICONDUCTOR STRUCTURE HAVING ACTIVE AREAS AND METHOD FOR MANUFACTURING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/976,472

(22) Filed: Dec. 11, 2024

Related U.S. Application Data
(63) Continuation-in-part of application No. 18/522,581, filed on Nov. 29, 2023.

(51) Int. Cl. H10B 12/00

(52) U.S. Cl. CPC H10B 12/488; H10B 12/312; H10B 12/485

(57) ABSTRACT

The present application discloses a semiconductor structure includes a substrate having an active area, dielectric structures, and word lines. The active area is located between the dielectric structures. The word lines are situated in the active area and are surrounded by a first insulating film over the substrate. Each word line includes a word line channel film inwardly positioned in the first insulating film and the substrate, a word line electrode disposed over and surrounded by the word line channel film, and a word line insulating film conformally disposed between the word line channel film and the word line electrode. A lower portion of the word line channel film penetrates an upper portion of the substrate, while an upper portion of the word line channel film is positioned in the first insulating film above a top surface of the substrate.

### CROSS-REFERENCE TO RELATED APPLICATION

This application is a continuation-in-part application of U.S. Non-Provisional application Ser. No. 18/522,581 filed Nov. 29, 2023, which is incorporated herein by reference in its entirety.

### TECHNICAL FIELD

The present disclosure relates to a semiconductor structure and a method for manufacturing the same, and more particularly, to a semiconductor structure with active areas and a patterning method for manufacturing the semiconductor structure.

### DISCUSSION OF THE BACKGROUND

Semiconductor devices are used in a variety of electronic applications, including personal computers, cellular telephones, digital cameras, and other electronic equipment. As the semiconductor industry advances into more advanced technology process nodes in pursuit of greater device density, dimensions of elements on a semiconductor substrate are reduced, leading to challenges in patterning smaller elements (e.g., active areas).

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure including a substrate with an active area; a plurality of first dielectric structures arranged within the substrate, wherein the active area is positioned between the first dielectric structures; and a plurality of word lines disposed in the active area and surrounded by a first insulating film over the substrate. Each of the word lines comprises a word line channel film inwardly positioned in the first insulating film and the substrate, a word line electrode disposed over and surrounded by the word line channel film, and a word line insulating film conformally disposed between the word line channel film and the word line electrode. The word line channel film includes a lower portion penetrating an upper portion of the substrate, and an upper portion positioned in the first insulating film above a top surface of the substrate.

Another aspect of the present disclosure provides a semiconductor structure including a substrate with an active area; a plurality of first dielectric structures arranged within the substrate, wherein the active area is positioned between the first dielectric structures; a first insulating film disposed over the substrate and the first dielectric structures; a second insulating film disposed over the first insulating film; a third insulating film disposed over the second insulating film; and a bit line contact comprising a first part positioned over a top surface of the substrate and a second part positioned over the first part. The first part is located within the first and second insulating films. The second part is located within the third insulating film.

Another aspect of the present disclosure provides a method for manufacturing a semiconductor structure. The method includes steps of: providing a substrate; forming an active area in the substrate; forming a plurality of first dielectric structures arranged within the substrate, wherein the active area is positioned between the first dielectric structures; forming a first insulating film over the substrate and in contact with the active area and the first dielectric structures; forming a trench in the first insulating film and the substrate; forming a plurality of word lines in the active area and the first insulating film; forming a bit line contact over the substrate; forming an air gap surrounding the bit line contact; and forming a capacitor contact over and in contact with the active area.

Another aspect of the present disclosure provides a method for manufacturing a semiconductor structure. The method includes steps of: providing a substrate including an active area; forming a plurality of first dielectric structures arranged within the substrate, wherein the active area is positioned between the first dielectric structures; forming a first insulating film in contact with the active area and the first dielectric structures; forming a plurality of trenches in the first insulating film and in the active area; respectively forming a plurality of word lines in the trenches; forming a second insulating film over the first insulating film; forming a neck portion of a capacitor contact and a first part of a bit line contact over the substrate and in the first and second insulating films; forming a third insulating film over the second insulating film; forming a head portion of the capacitor contact over the neck portion and in the third insulating film; forming a fourth insulating film over the third insulating film; forming a contact plug over and in contact with the head portion of the capacitor contact; forming a second part of the bit line contact; and forming a bit line over the second part of the bit line contact.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic top-view diagram of a substrate in accordance with some embodiments of the present disclosure.

FIG. 2 is a schematic top-view diagram of the substrate after formation of several recessed portions in accordance with some embodiments of the present disclosure.

FIG. 3 is a schematic cross-sectional diagram along a line D-D′ in FIG. 2 in accordance with some embodiments of the present disclosure.

FIG. 4 is a schematic top-view diagram at a stage after that of FIG. 2 in accordance with some embodiments of the present disclosure.

FIG. 5 is a schematic cross-sectional diagram along a line D-D′ in FIG. 4 in accordance with some embodiments of the present disclosure.

FIG. 6 is a schematic top-view diagram at a stage after that of FIG. 4 in accordance with some embodiments of the present disclosure.

FIG. 7 is a schematic cross-sectional diagram along a line D-D′in FIG. 6 in accordance with some embodiments of the present disclosure.

FIG. 8 is a schematic top-view diagram at a stage after that of FIG. 7 in accordance with some embodiments of the present disclosure.

FIGS. 9A, 10A, 11A, 12A, 13A, 14A, 15A, 16A, 17A, 19A, 20A, 21A, 22A and 24A are schematic cross-sectional diagrams along a line A-A′ in FIG. 8 at different stages of the method in accordance with some embodiments of the present disclosure.

FIGS. 9B, 10B, 11B, 12B, 13B, 14B, 15B, 16B, 17B, 19B, 20B, 21B, 22B and 24B are schematic cross-sectional diagrams along a line B-B′in FIG. 8 at different stages of the method in accordance with some embodiments of the present disclosure.

FIGS. 9C, 10C, 11C, 12C, 13C, 14C, 15C, 16C, 17C, 19C, 20C, 21C, 22C and 24C are schematic cross-sectional diagrams along a line C-C′ in FIG. 8 at different stages of the method in accordance with some embodiments of the present disclosure.

FIG. 18 is a schematic top-view diagram at a stage of a method shown in

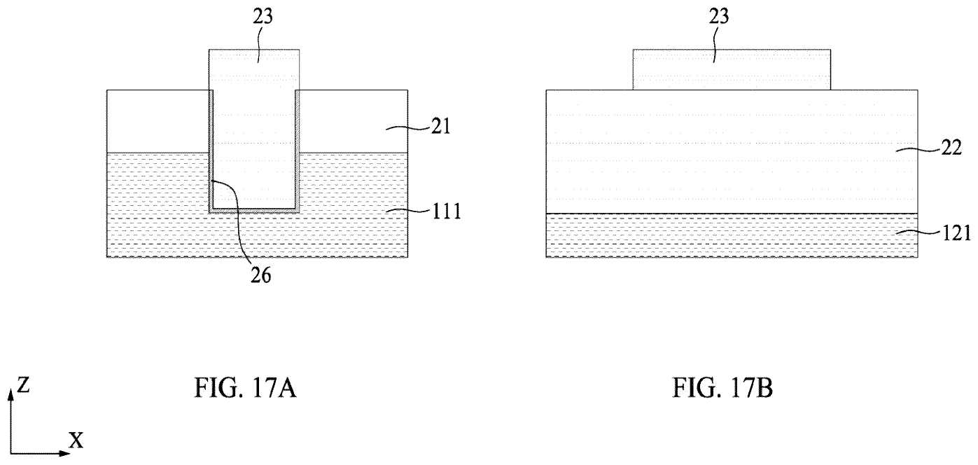

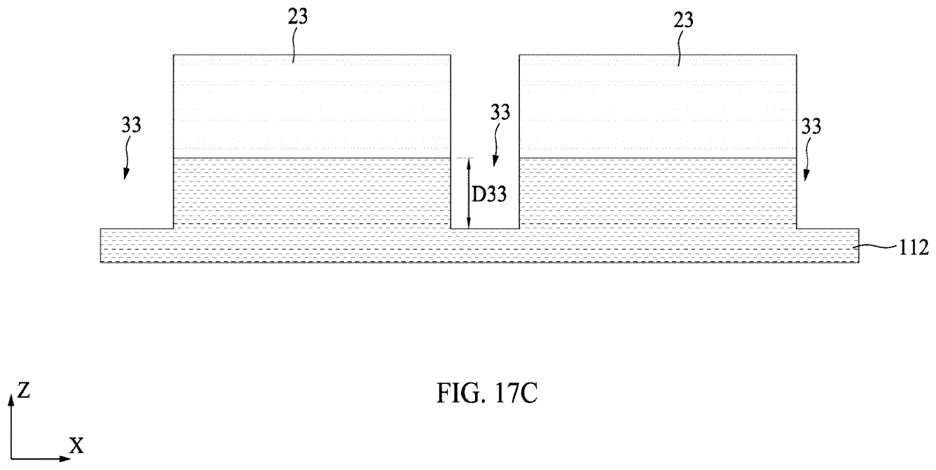

FIGS. 17A, 17B and 17C in accordance with some embodiments of the present disclosure.

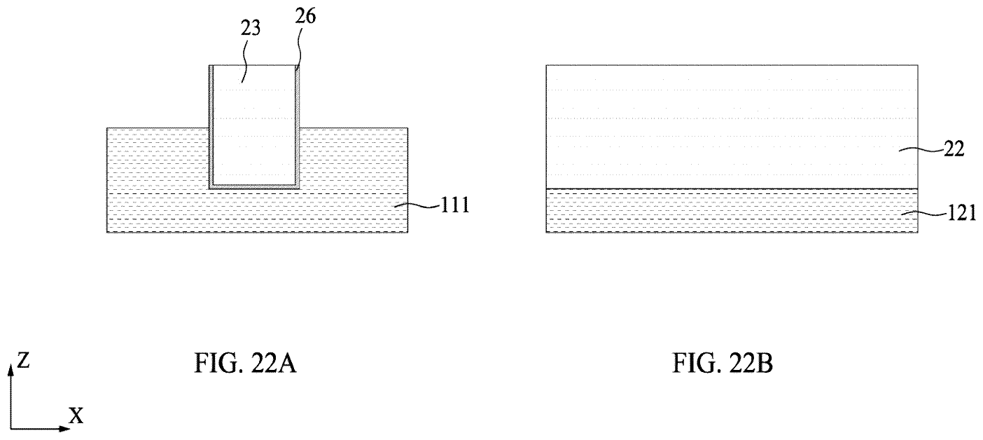

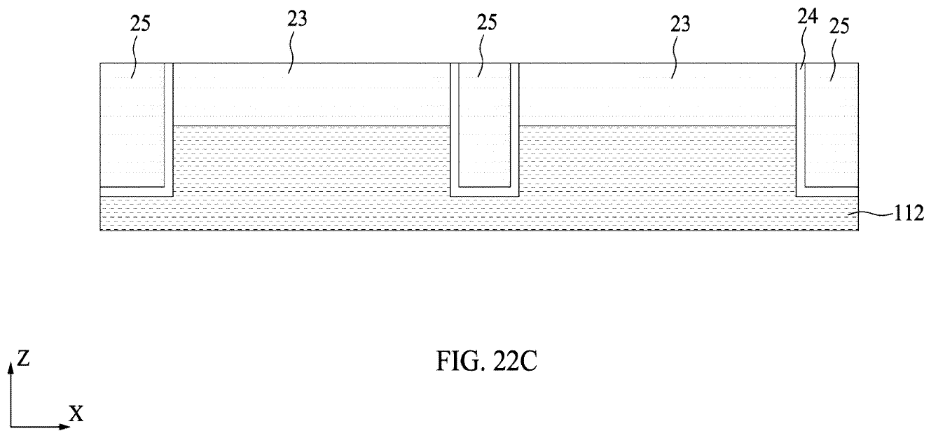

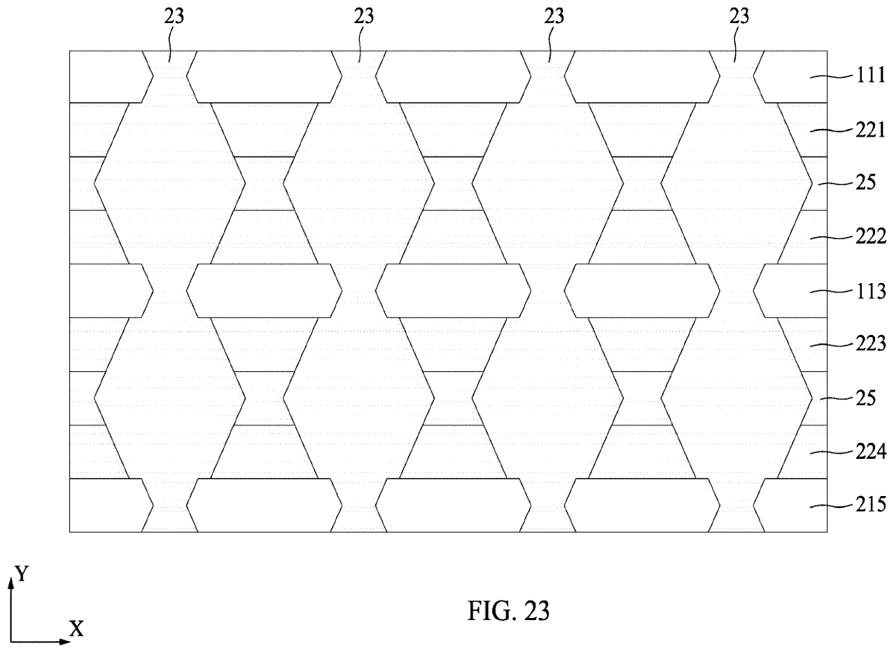

FIG. 23 is a schematic top-view diagram at a stage of a method shown in FIGS. 22A, 22B and 22C in accordance with some embodiments of the present disclosure.

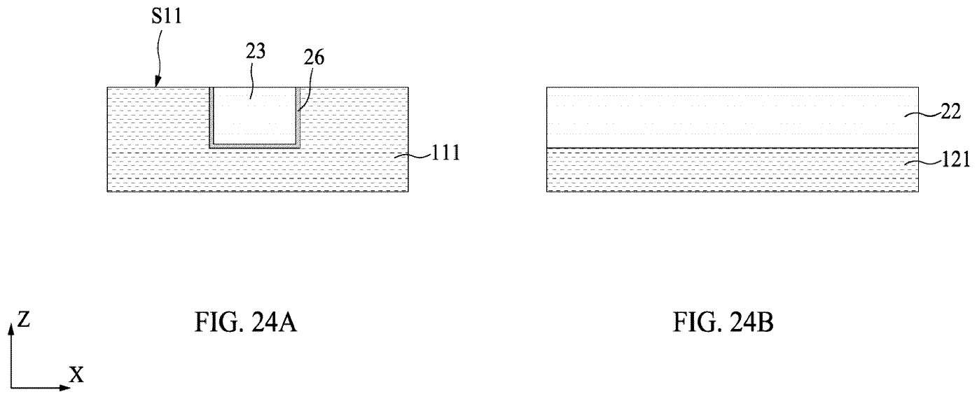

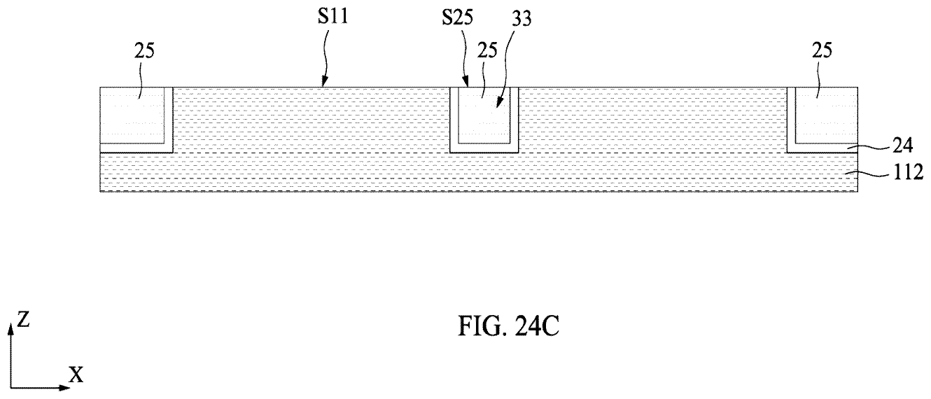

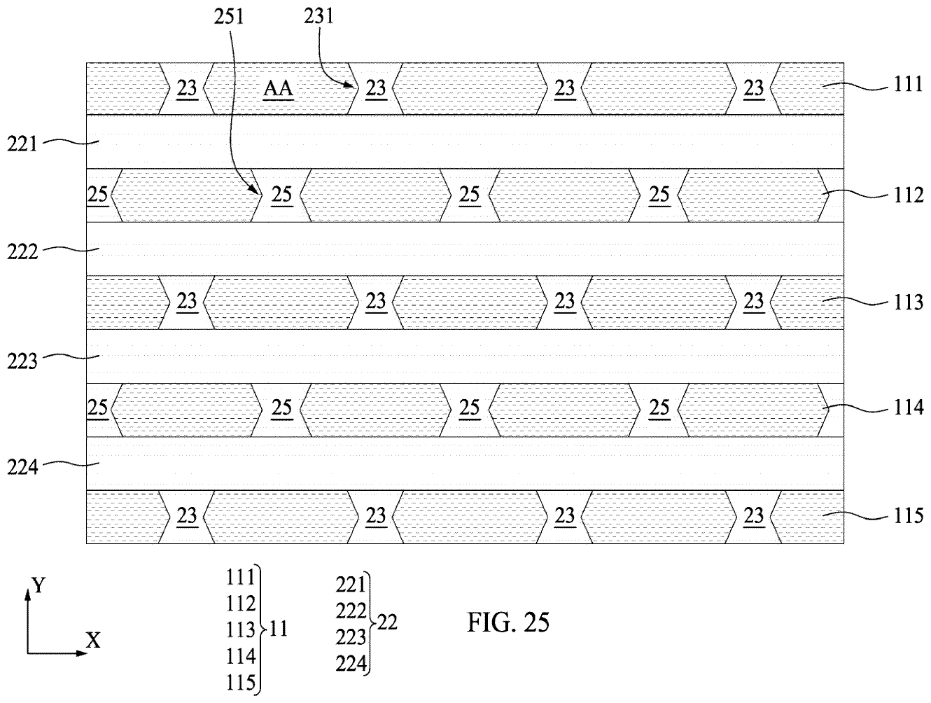

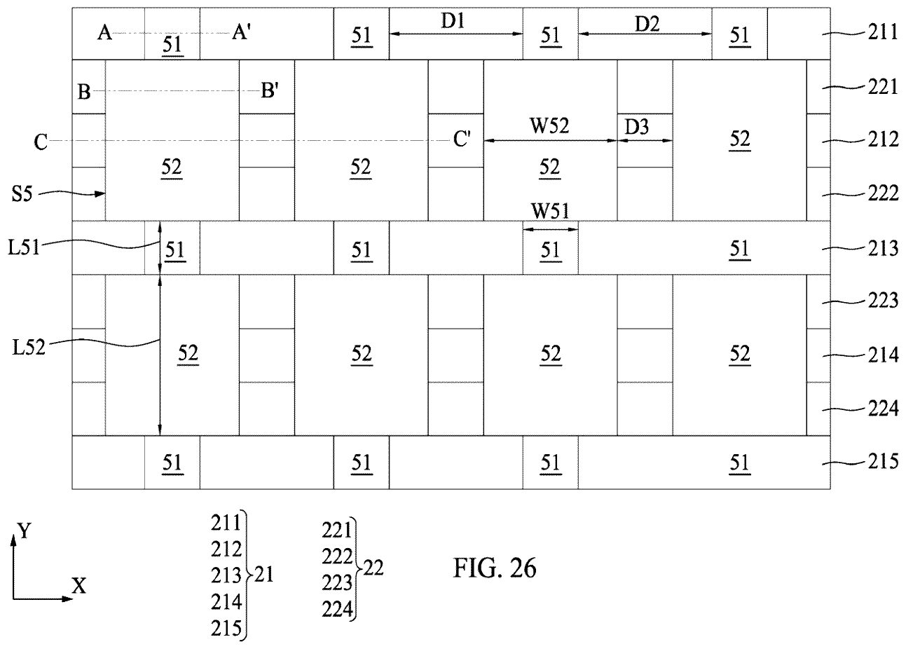

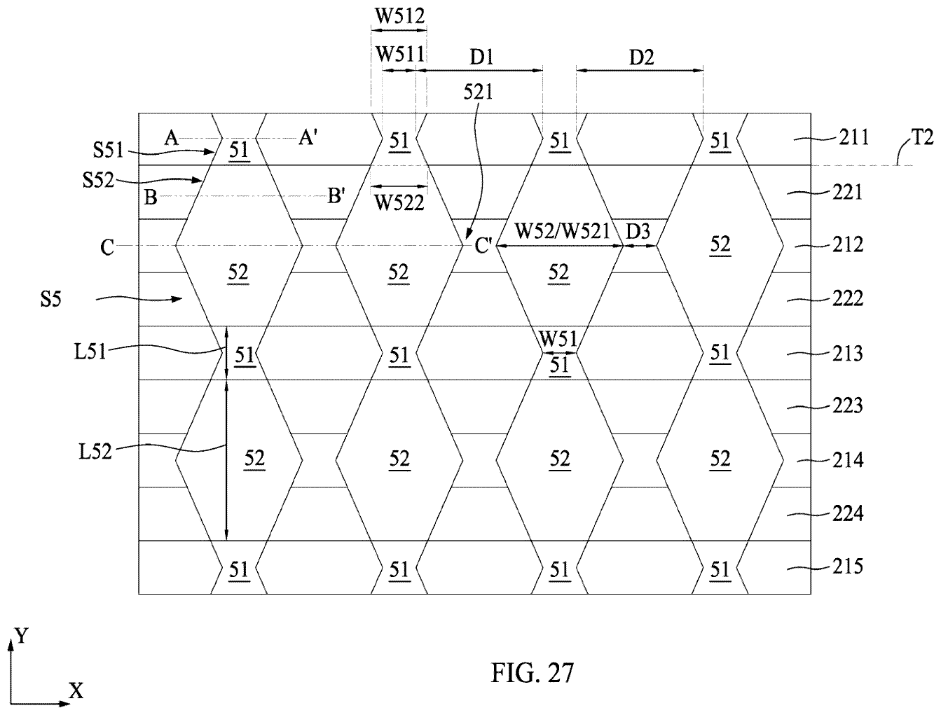

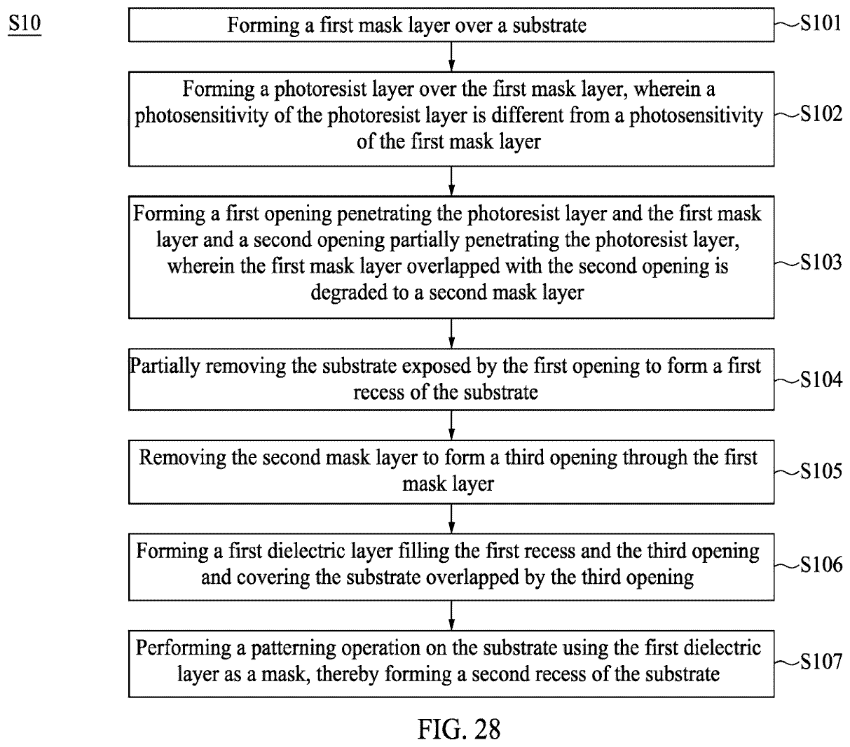

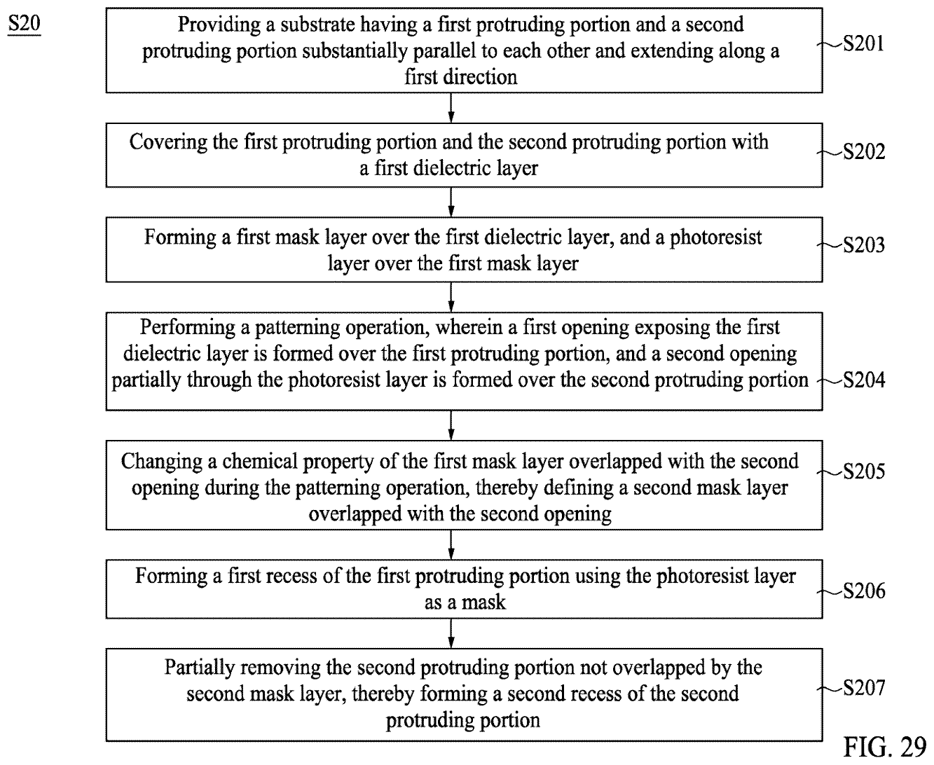

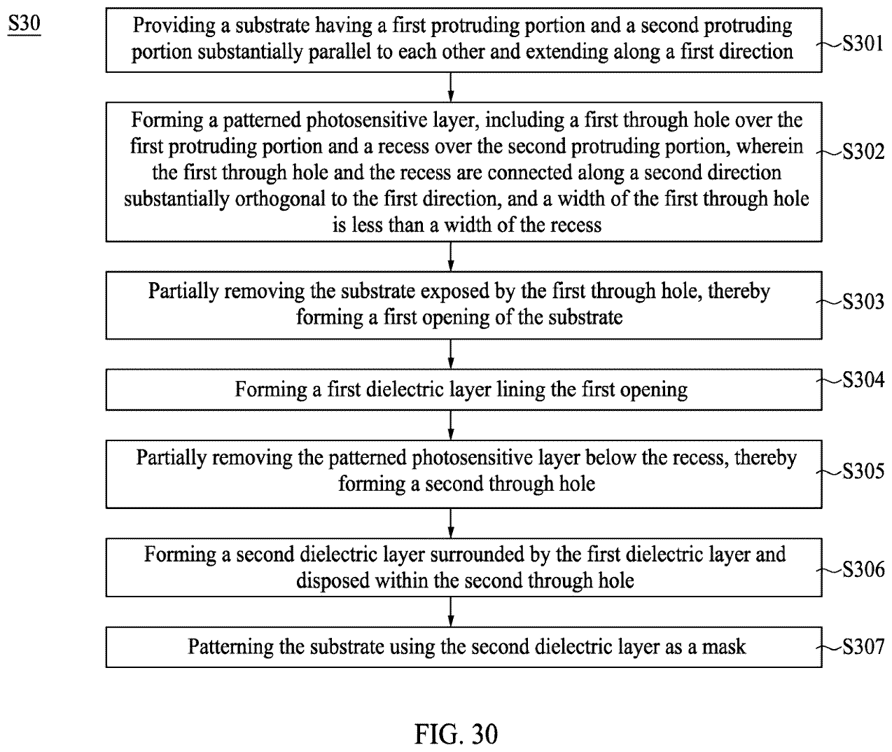

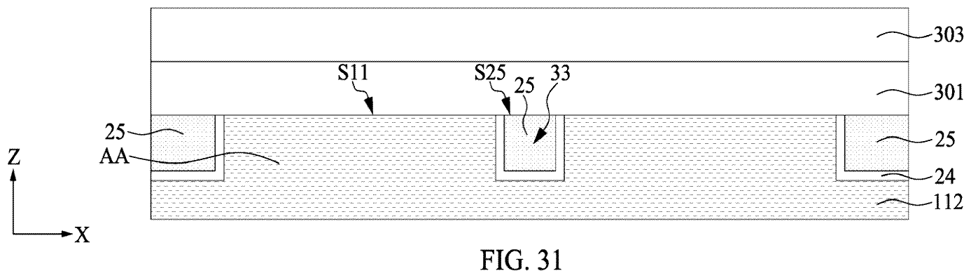

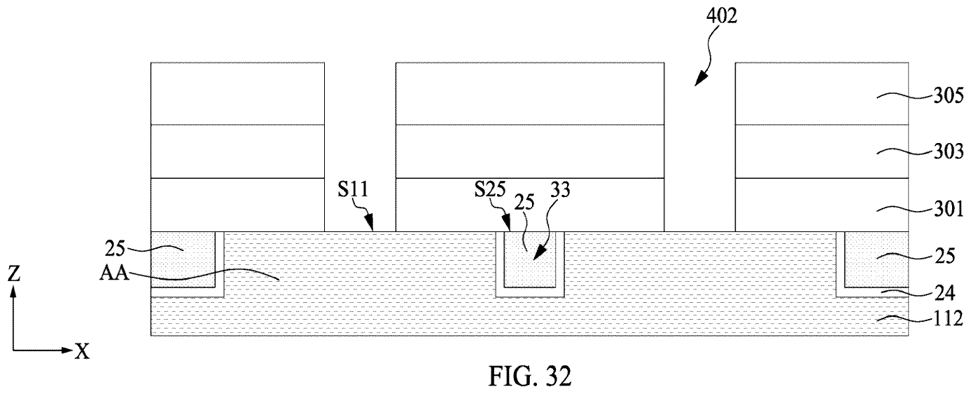

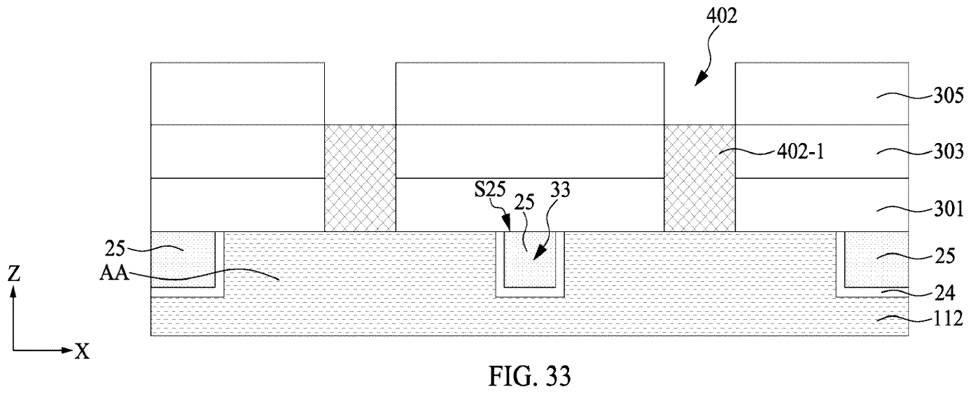

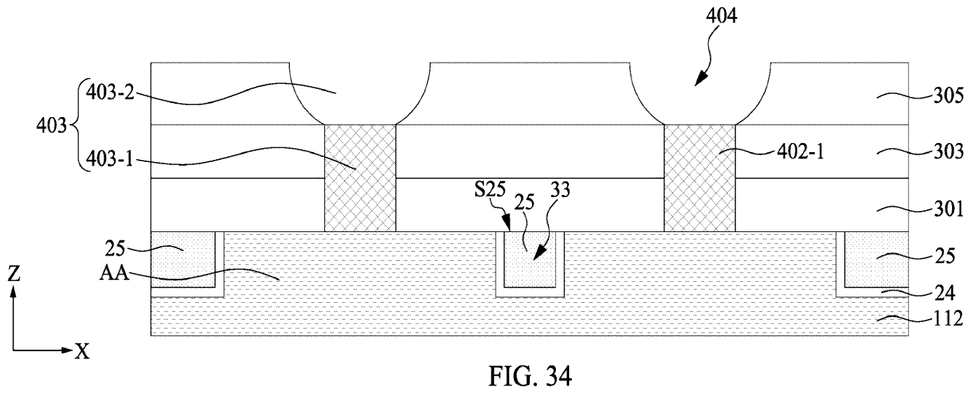

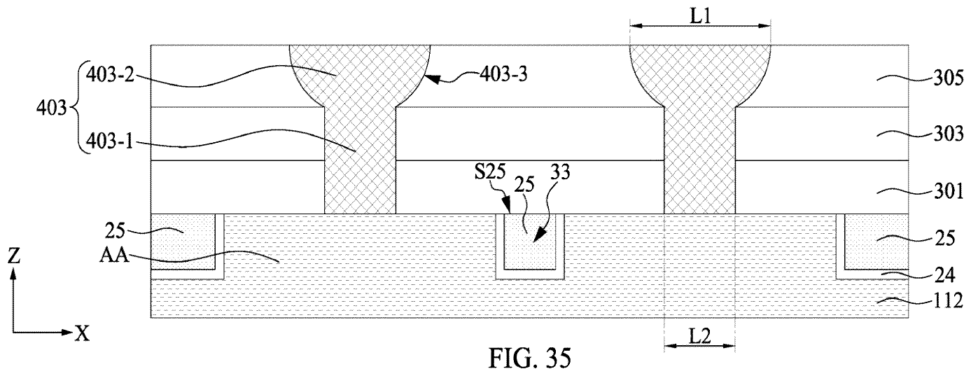

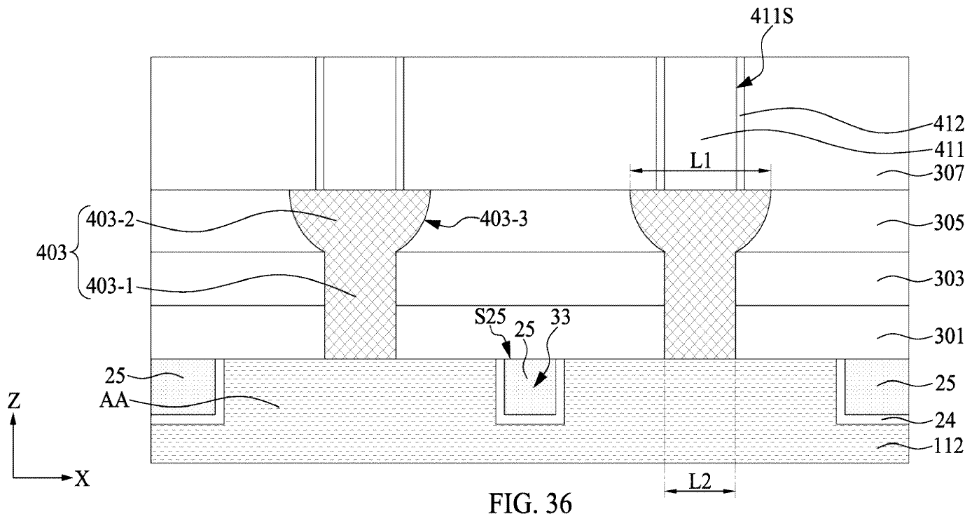

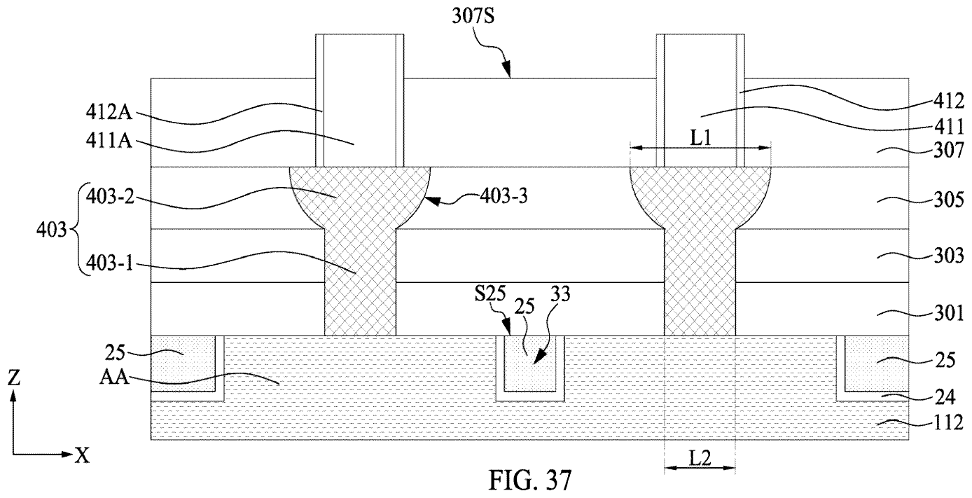

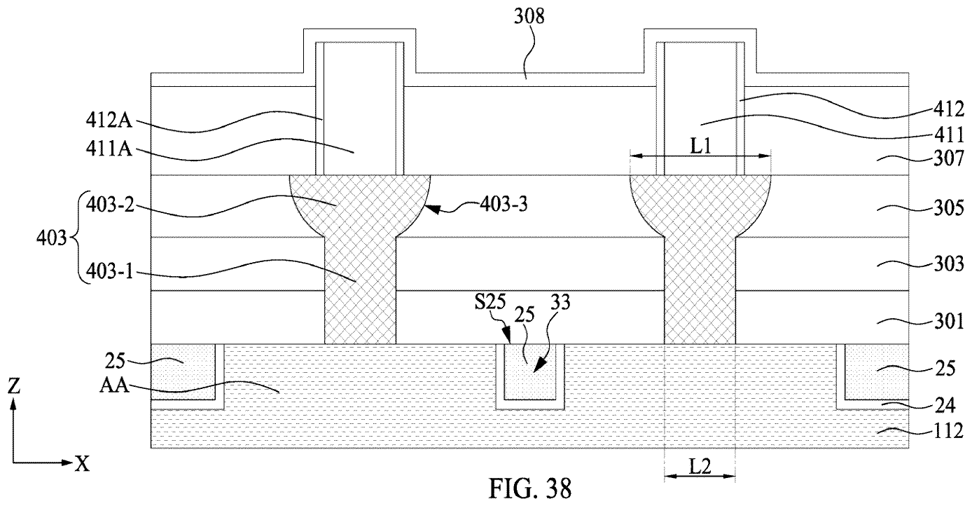

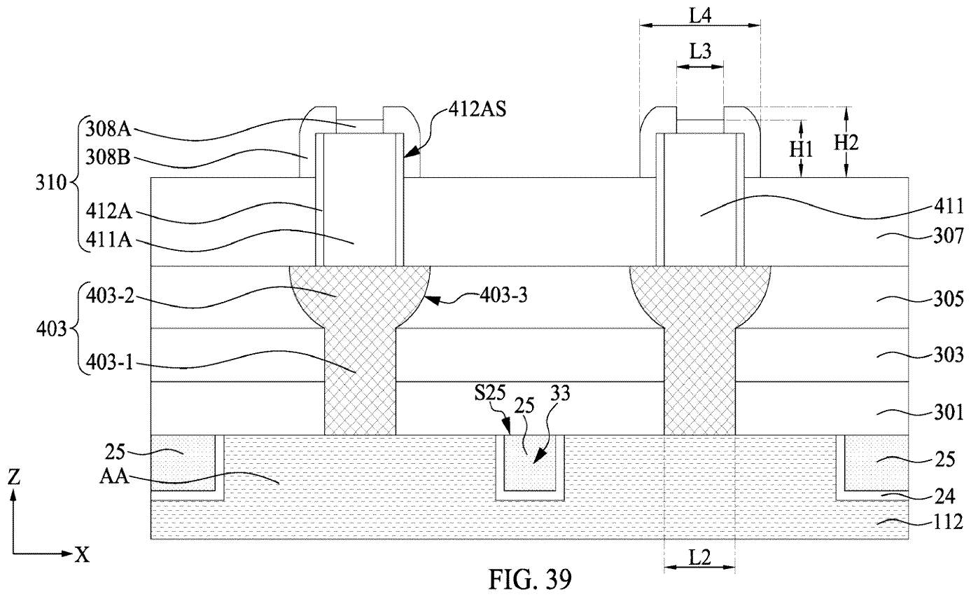

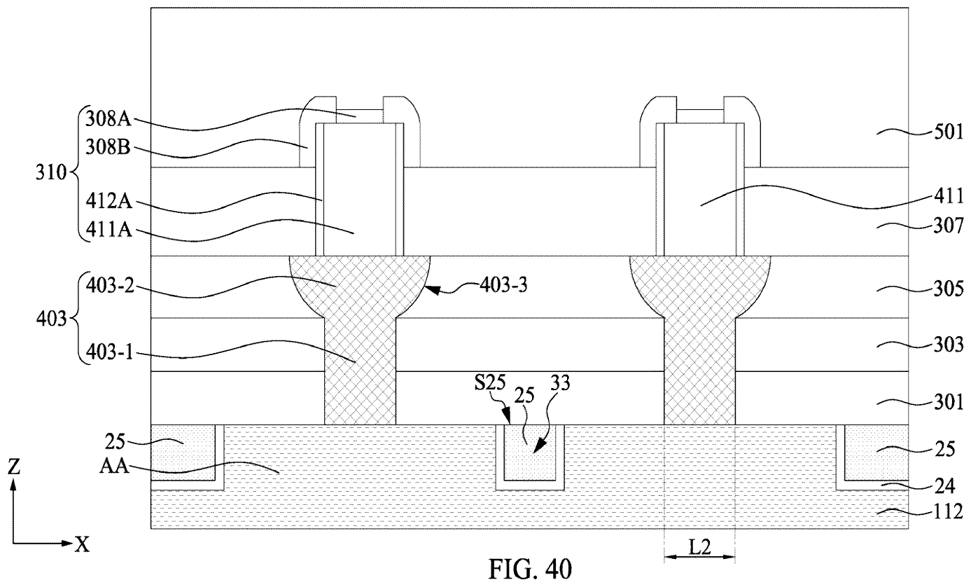

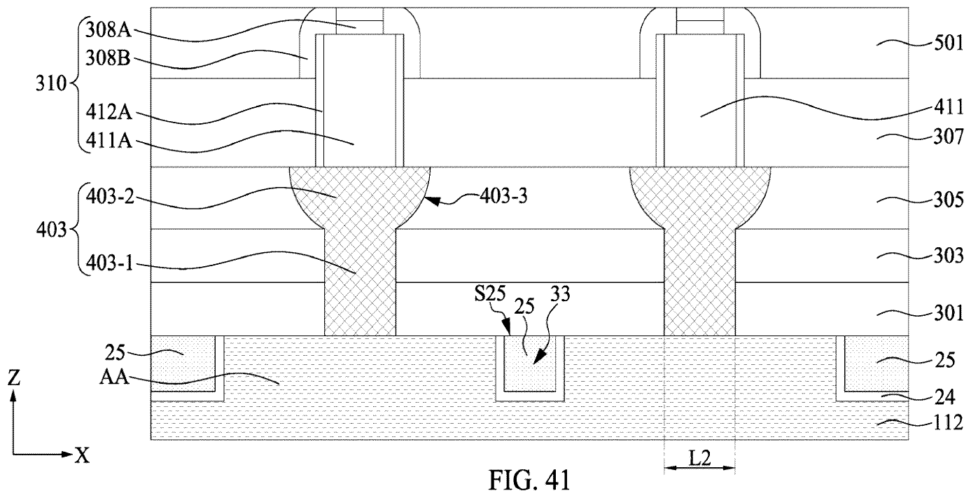

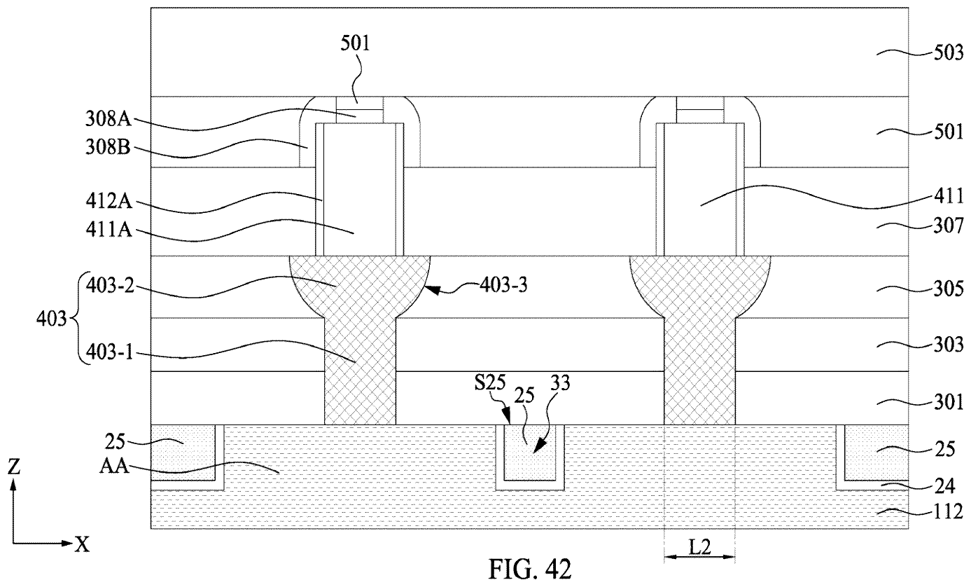

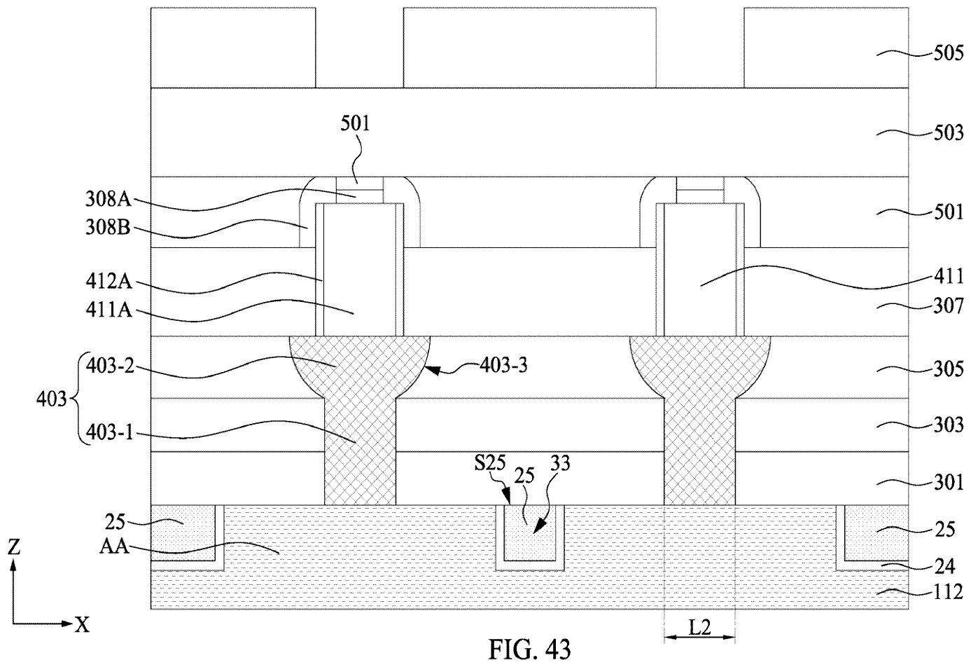

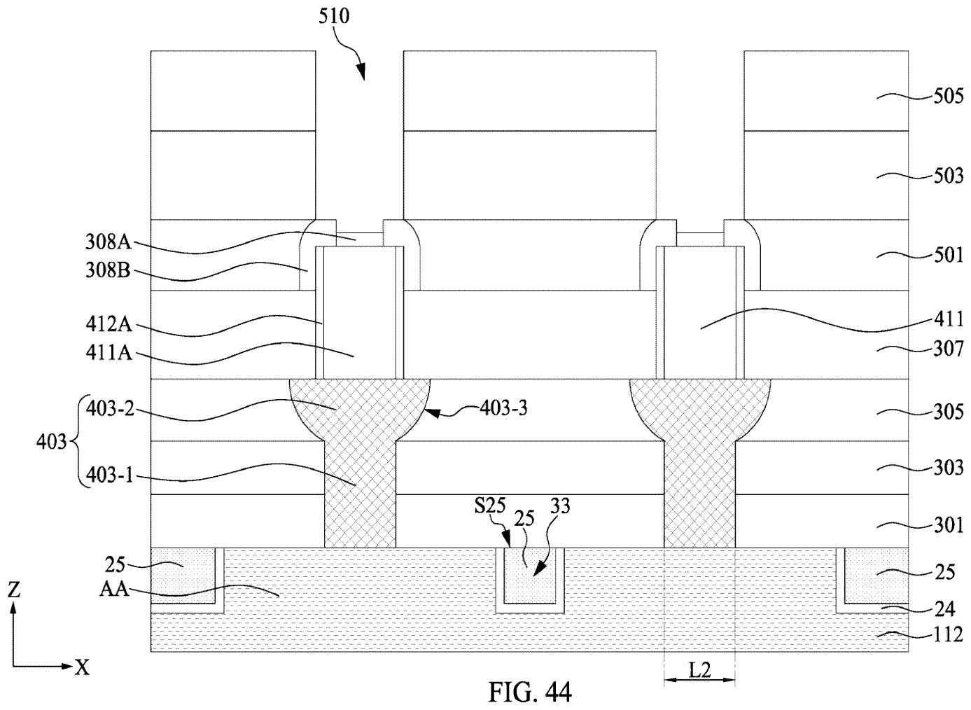

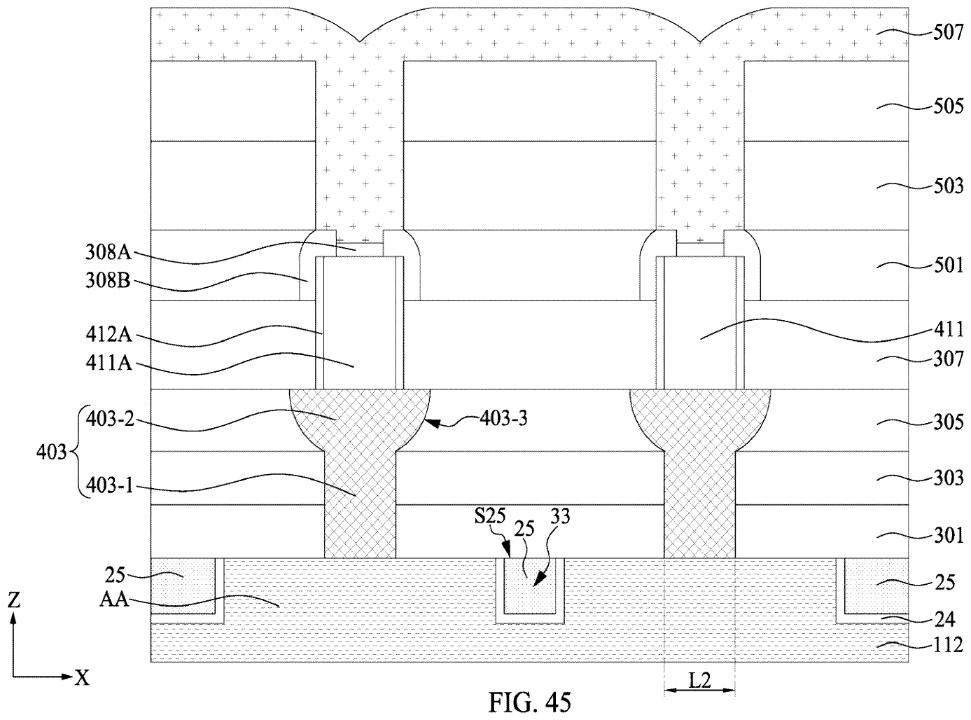

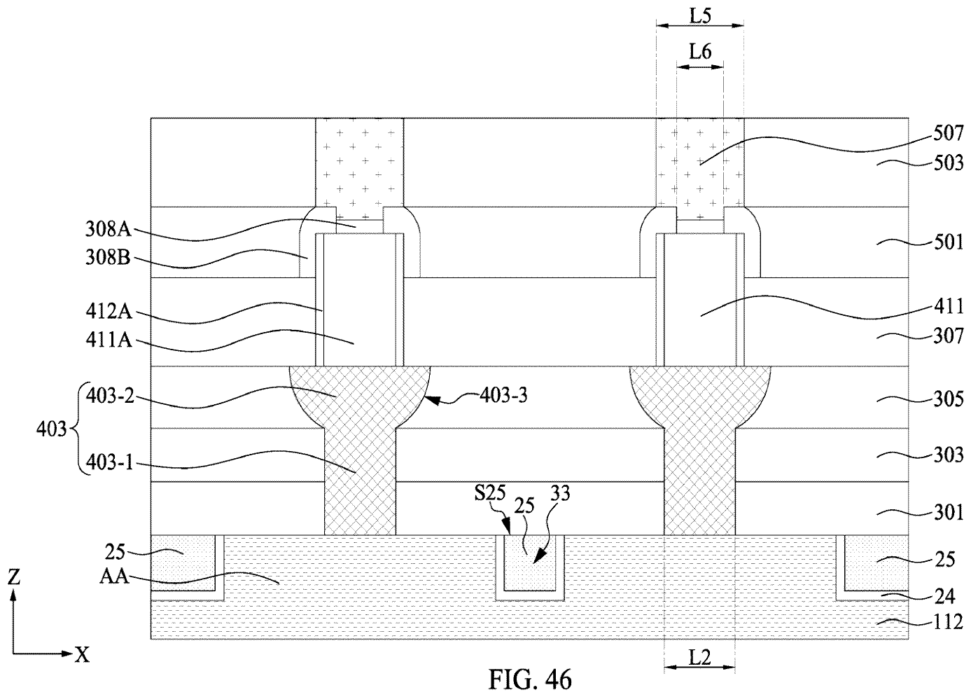

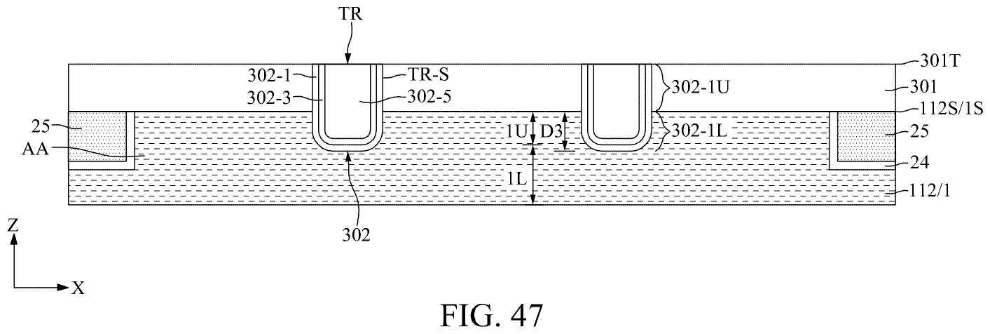

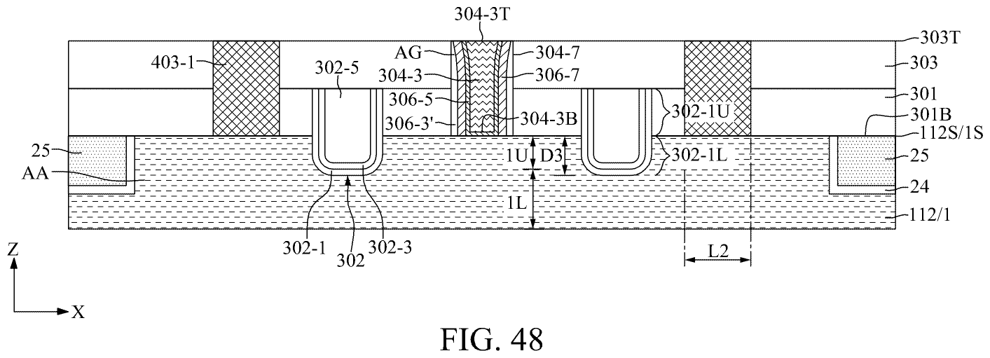

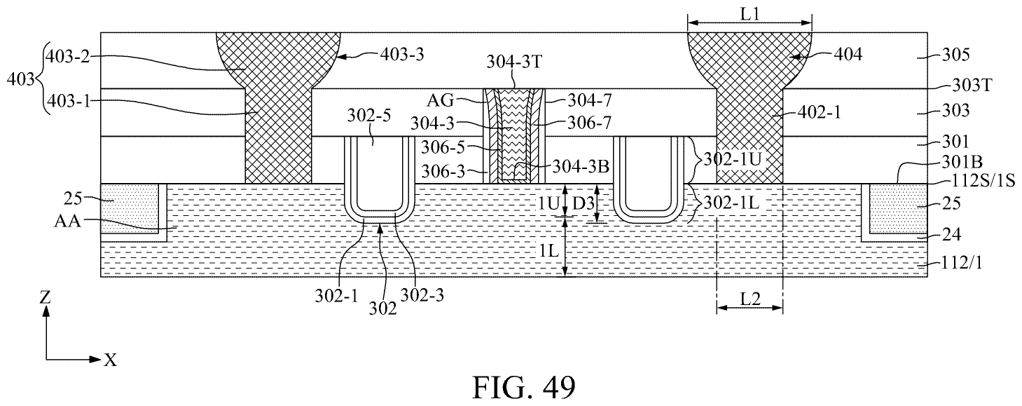

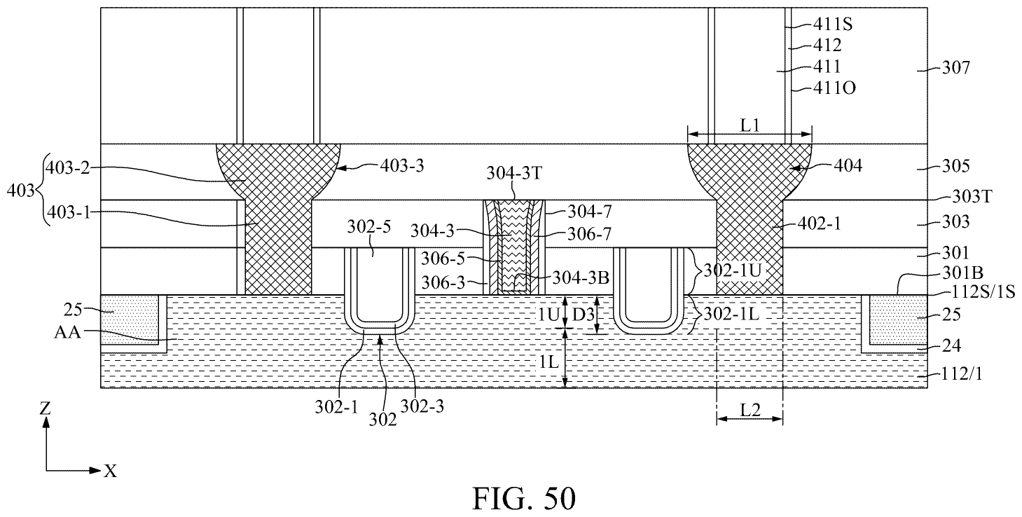

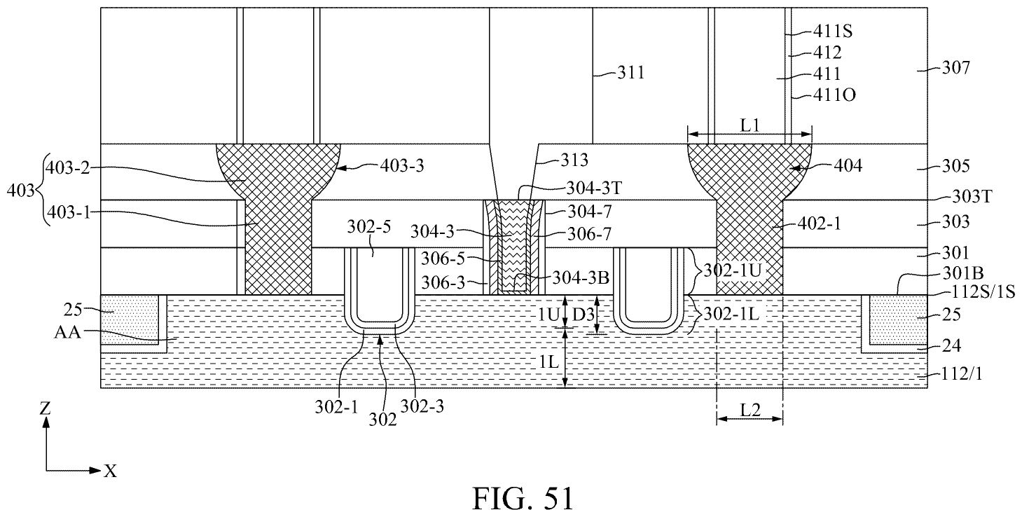

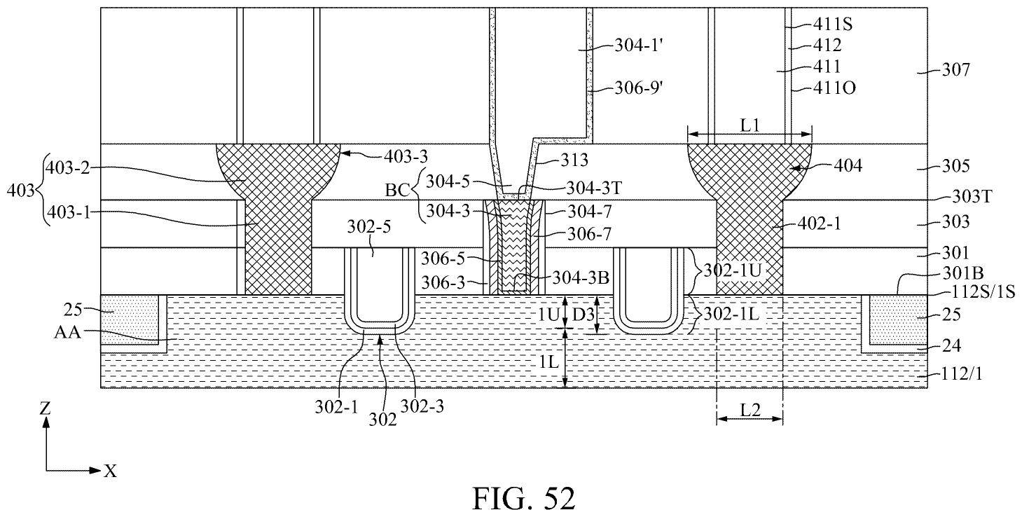

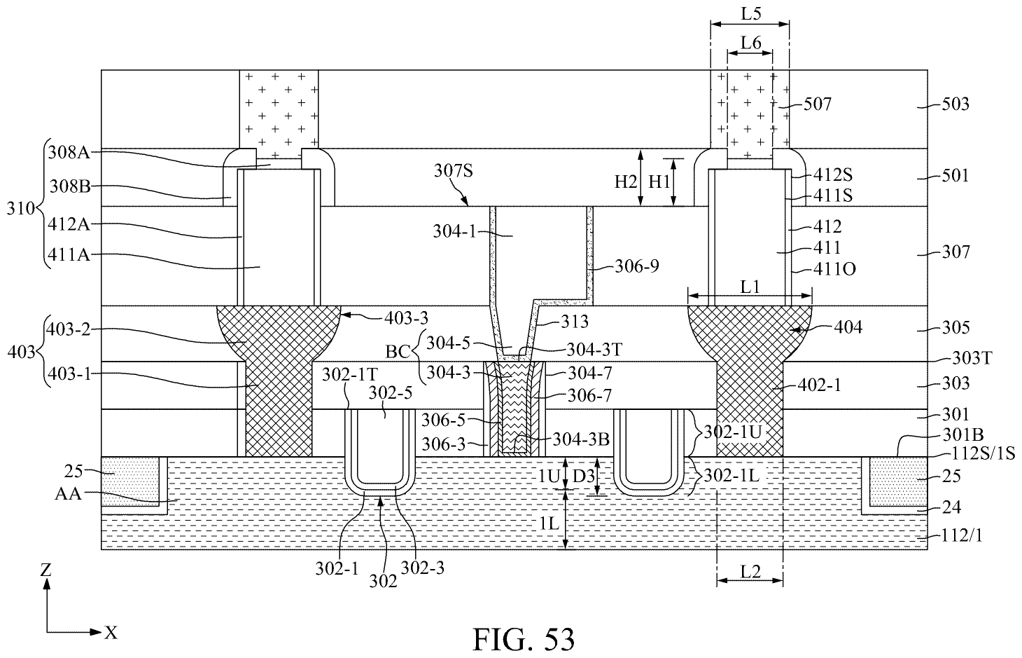

FIG. 25 is a schematic top-view diagram at a stage of a method shown in FIGS. 24A, 24B and 24C in accordance with some embodiments of the present disclosure.

FIGS. 26 and 27 are schematic top-view diagrams of a patterned photosensitive layer at a stage of the method in accordance with different embodiments of the present disclosure.

FIGS. 28, 29 and 30 are flow diagrams illustrating methods for manufacturing a semiconductor structure in accordance with some embodiments of the present disclosure.

FIGS. 31 to 39 are schematic cross-sectional diagrams of a method for forming a capacitor contact and a landing pad over an active area in accordance with some embodiments of the present disclosure.

FIGS. 40 to 46 are schematic cross-sectional diagrams of a method for forming a metal plug over a landing pad in accordance with some embodiments of the present disclosure.

FIGS. 47 to 53 are schematic cross-sectional diagrams of a method for forming word lines, a bit line contact, and a bit line in accordance with various embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Due to a trend of shrinking sizes in semiconductor devices, dimensions of active areas may become so small that precise definition of the active areas is difficult to achieve with electron beam lithography (EBL). With the advent of extreme ultraviolet lithography (EUVL), patterns with dimensions less than 37 nanometers (nm) can be produced. However, equipment and processes associated with EUVL are expensive, leading to increased process and product costs.

The present disclosure provides a method for forming multiple active areas on a substrate using EBL. Photosensitive materials with varying photosensitivities are employed to define active areas arranged in different rows, enabling achievement of smaller dimensions (e.g., a pattern with a width or a length less than 37 nanometers).

Schematic diagrams of a substrate at different stages of the method described in the present disclosure are provided in the figures, accompanied by descriptions in the following paragraphs to illustrate concepts of the disclosure.

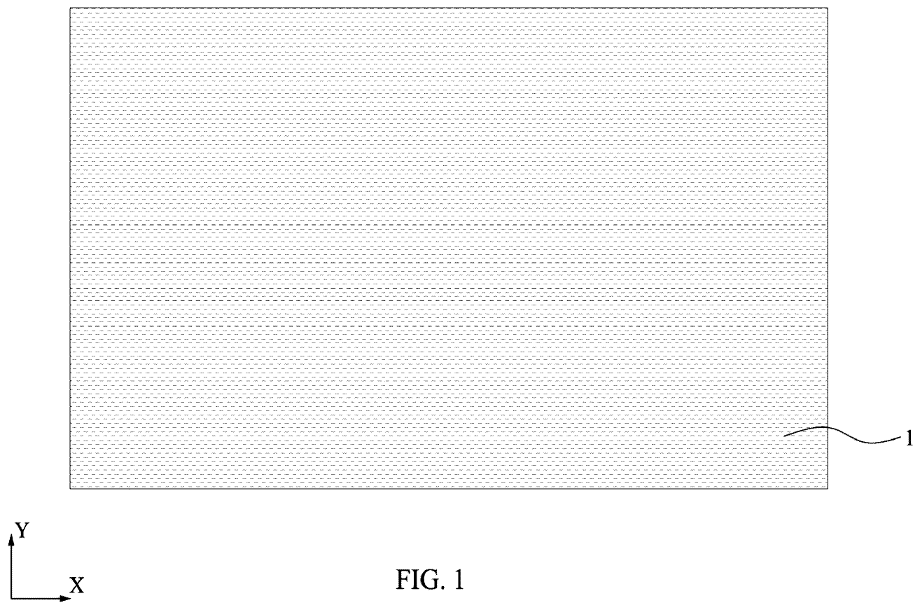

With reference to FIG. 1, a substrate 1 is provided, formed or received. The substrate 1 may include semiconductive material. In some embodiments, the substrate 1 includes a material selected from III-V groups on the periodic table. In some embodiments, the substrate 1 is a bulk semiconductor, a semiconductor-on-insulator (SOI) substrate, or the like. The substrate 1 may be of a first conductivity type, such as a P-type semiconductive substrate (acceptor type), or of a second conductivity type, such as an N-type semiconductive substrate (donor type). In some embodiments, the substrate 1 may include a doped epitaxial layer, a gradient semiconductor layer, or a semiconductor layer overlaying another semiconductor layer of a different type, such as a silicon layer on a silicon germanium layer.

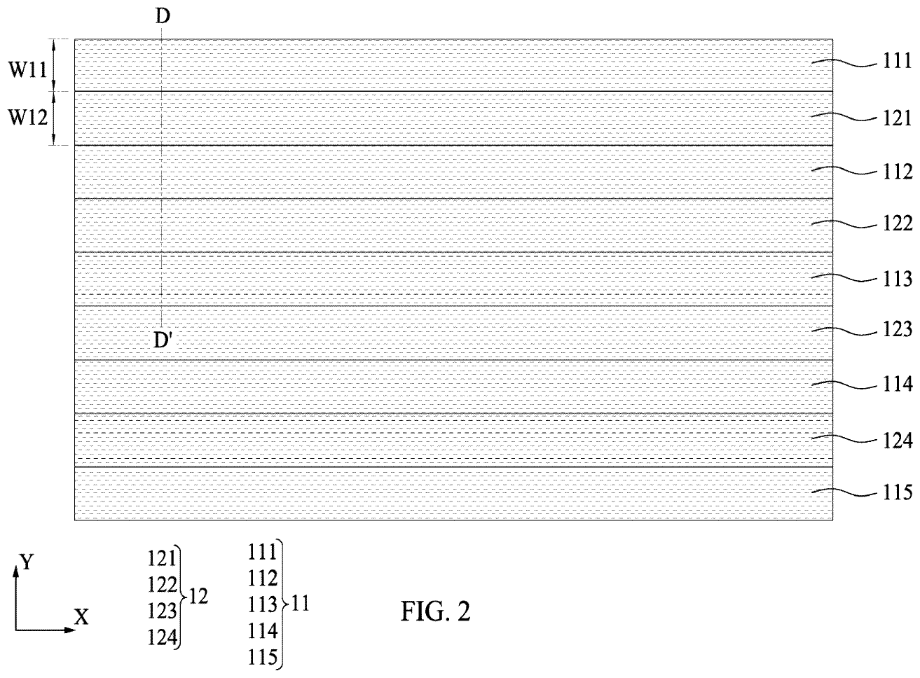

With reference to FIG. 2, portions of the substrate 1 are removed, resulting in formation of a plurality of protruding portions 11 and a plurality of recessed portions 12. The protruding portions 11 and the recessed portions 12 are alternately arranged along a first direction (e.g., the Y direction). In some embodiments, each of the protruding portions 11 extends along a second direction (e.g., the X direction), which is substantially orthogonal to the first direction. Similarly, each of the recessed portions 12 also extends along the second direction. In some embodiments, the protruding portions 11 and the recessed portions 12 are substantially parallel. In some embodiments, each of the protruding portions 11 has a width W11 measured along the first direction that is substantially equal to a width W12 of each of the recessed portions 12, also measured along the first direction.

In some embodiments, the plurality of protruding portions 11 includes a first protruding portion 111, a second protruding portion 112, a third protruding portion 113, a fourth protruding portion 114, and a fifth protruding portion 115. The protruding portions 111 to 115 are arranged serially along the first direction, with adjacent protruding portions 11 separated by a recessed portion 12. In some embodiments, the plurality of recessed portions 12 includes a first recessed portion 121, a second recessed portion 122, a third recessed portion 123, and a fourth recessed portion 124. The recessed portions 121 to 124 are also arranged serially along the first direction. It should be noted that a number of the protruding portions 11 and a number of the recessed portions 12 shown in the figures are for illustrative purposes only and are not limited herein.

It should be noted that lengths of the protruding portions 11 and lengths of the recessed portions 12 can be adjusted depending on a scale of a semiconductor structure. The method of the present disclosure includes formation of active areas AA of an advanced generation of semiconductor structures, wherein the active areas AA are formed on the protruding portions 11 and have substantially equal sizes, interlaced along the first direction (as shown in FIG. 25). More detailed information is described below.

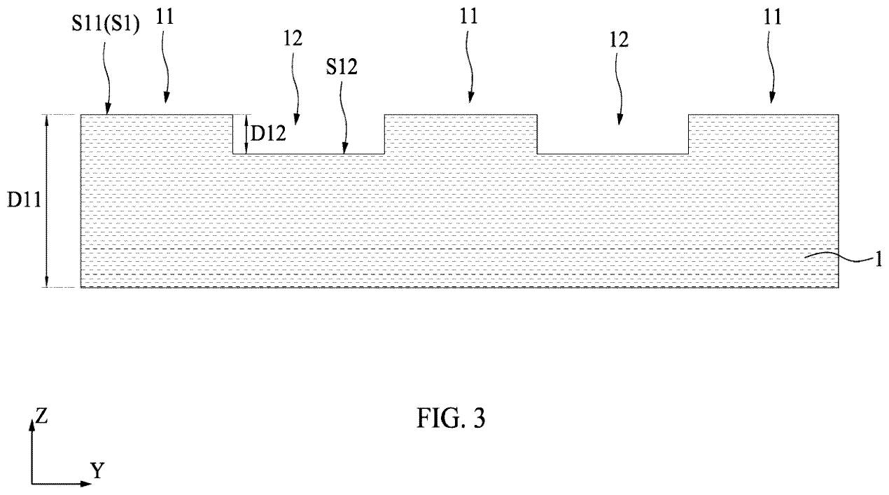

FIG. 3 is a cross-sectional diagram along a line D-D′ in FIG. 2. With reference to FIG. 3, in some embodiments, a top surface S11 of the protruding portion 11 defines a top surface S1 of the substrate 1. In some embodiments, a thickness D11 of the substrate 1 is approximately 775 microns (μm). The recessed portion 12 is recessed from the top surface S1 of the substrate 1 by a distance D12 in the range of 0.1 to 1 μm. In other words, a top surface S12 of the recessed portion 12 is lower than the top surface S11 of the protruding portion 11 by the distance D12.

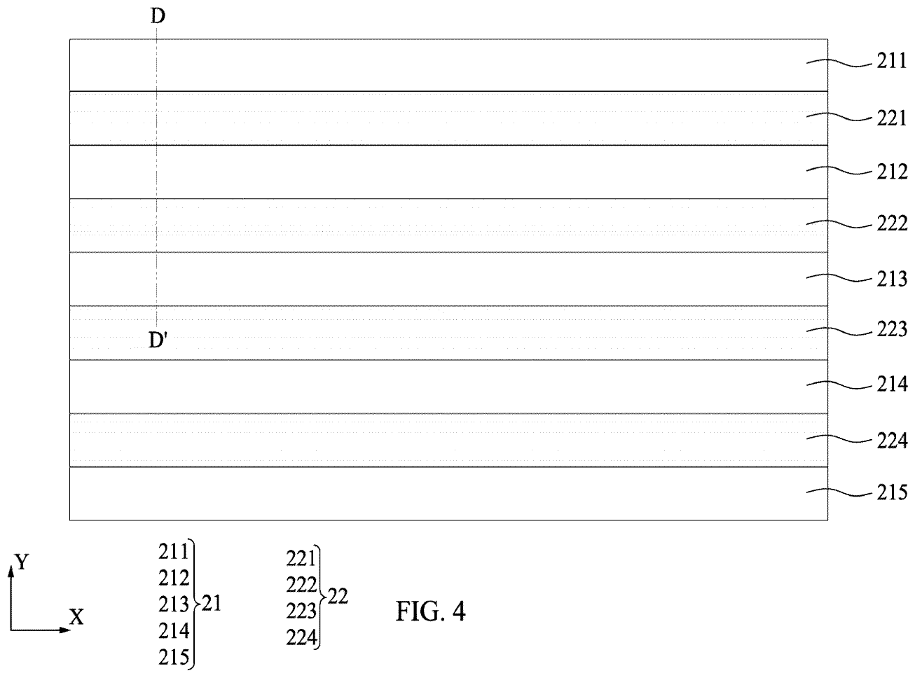

With reference to FIG. 4, a first dielectric layer 21 and a second dielectric layer 22 are formed over the substrate 1. The first dielectric layer 21 and the second dielectric layer 22 consist of different dielectric materials. In some embodiments, the first dielectric layer 21 and the second dielectric layer 22 have different etching rates when subjected to an etchant. In some embodiments, the first dielectric layer 21 comprises nitride, while the second dielectric layer 22 comprises oxide. The first dielectric layer 21 covers the protruding portions 11, and the second dielectric layer 22 covers the recessed portions 12. In some embodiments, the first dielectric layer 21 includes multiple first segments (e.g., 211, 212, 213, 214 and 215) disposed over and corresponding to the protruding portions 111 to 115. Similarly, the second dielectric layer 22 includes multiple second segments (e.g., 221, 222, 223 and 224) disposed over and corresponding to the recessed portions 121 to 124. As shown in FIG. 4, each segment of the first dielectric layer 21 and each segment of the second dielectric layer 22 individually has a bar configuration extending along the second direction. In some embodiments, the multiple first segments and the multiple second segments are alternately arranged along the first direction.

In some embodiments, each of the first segments 211, 212, 213, 214 and 215 of the first dielectric layer 21 and each of the second segments 221, 222, 223 and 224 of the second dielectric layer 22 are substantially parallel along the second direction. For ease of illustration, the last digit of the numeral for a first segment indicates a position in the order of the first segments along the first direction, while the last digit of the numeral for a second segment indicates a position in the order of the second segments along the first direction. In other words, the first two digits of the numeral for a segment indicate which dielectric layer 21 or 22 the segment belongs to, and the last digit indicates the position in the order along the first direction.

For example, the first segment 211 is the first among the multiple first segments 211 to 215 along the first direction, while the second segment 221 is the first among the multiple second segments 221 to 224. The second segment 221 is positioned between the first segments 211 and 212 along the first direction, and the first segment 212 is positioned between the second segments 221 and 222 along the first direction, and so forth.

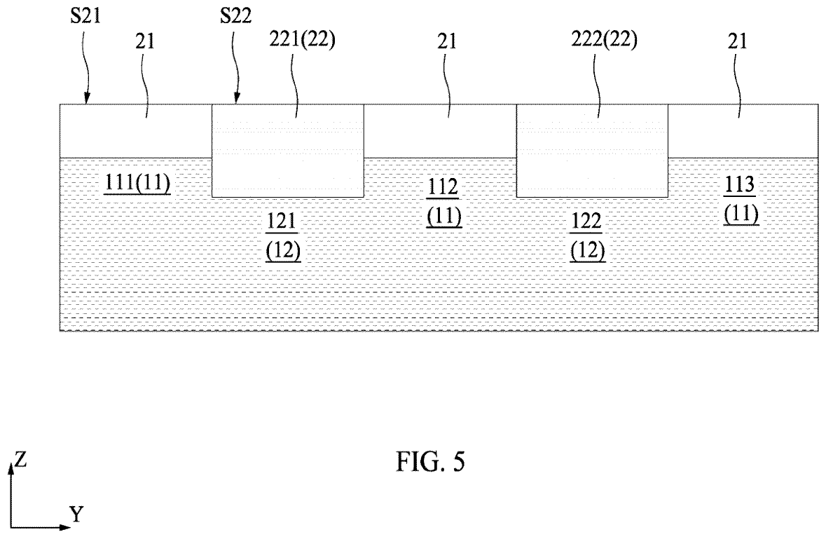

FIG. 5 is a cross-sectional diagram along line D-D′ in FIG. 4. With reference to FIG. 5, a top surface S21 of the first dielectric layer 21 may be substantially aligned with or coplanar with a top surface S22 of the second dielectric layer 22. The formation of the first and second dielectric layers 21 and 22 may involve multiple operations.

In some embodiments, the first dielectric layer 21 is formed prior to the formation of the second dielectric layer 22. A deposition of the first dielectric layer 21 may be performed, followed by an etching operation to expose the recessed portions 12 of the substrate 1. Subsequently, a deposition of the second dielectric layer 22 may be performed, followed by another etching operation to remove excess portions of the second dielectric layer 22 that are disposed over the first dielectric layer 21. In some embodiments, a planarization process is performed to achieve the coplanar top surfaces S21 and S22 of the first and second dielectric layers 21 and 22, as shown in FIG. 5.

In some embodiments, the second dielectric layer 22 is formed prior to the formation of the first dielectric layer 21. The operations may be similar to those described above, and repeated descriptions are omitted.

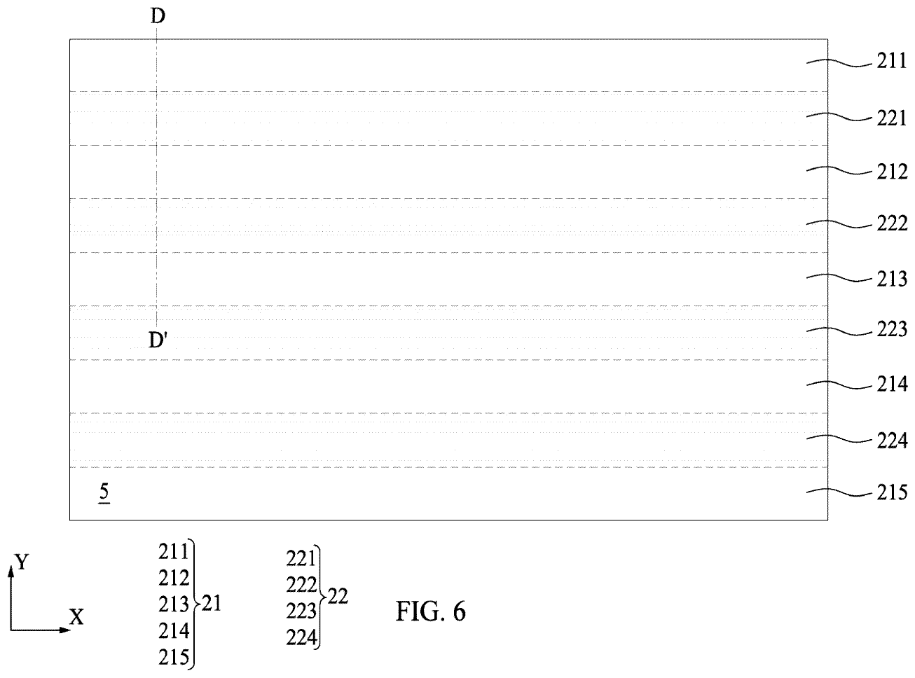

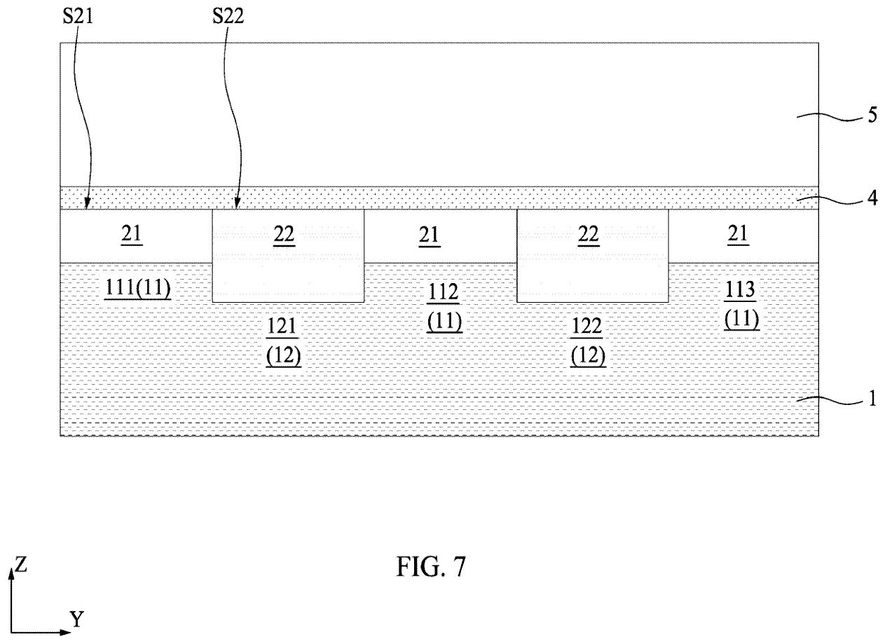

With reference to FIGS. 6 and 7, a first mask layer 4 and a photoresist layer 5 are sequentially formed over the first dielectric layer 21 and the second dielectric layer 22. The first mask layer 4 may be sensitive to light illumination. In some embodiments, the first mask layer 4 and the photoresist layer 5 together are referred to as a photosensitive layer or a photosensitive structure. In some embodiments, the first mask layer 4 is referred to as a lower sub-layer, while the photoresist layer 5 is referred to as an upper sub-layer of the photosensitive layer. In some embodiments, the first mask layer 4 and the photoresist layer 5 consist of different polymers. Additionally, in some embodiments, a photosensitivity or an optical sensitivity of the photoresist layer 5 differs from that of the first mask layer 4. In some embodiments, the first mask layer 4 is also referred to as a photosensitive layer. Furthermore, the photoresist layer 5 may include a positive photoresist material, and the first mask layer 4 may include a positive photosensitive material. In some embodiments, the first mask layer 4 is in contact with both the first dielectric layer 21 and the second dielectric layer 22. In some embodiments, the first mask layer 4 is formed over a planar surface defined by the top surface S21 of the first dielectric layer 21 and the top surface S22 of the second dielectric layer 22.

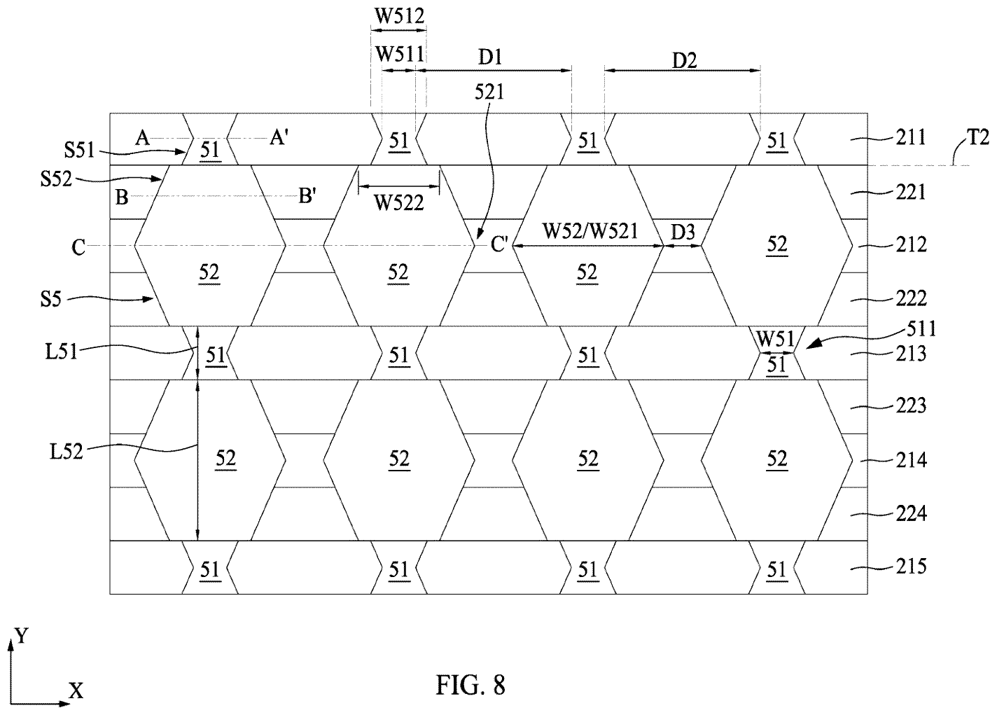

With reference to FIG. 8, a plurality of openings (e.g., 51 and 52) are formed in both the photoresist layer 5 and the first mask layer 4 (a detailed description is provided below). The plurality of openings may include groups of openings with varying depths and sizes.

From a top view shown in FIG. 8, a plurality of first openings 51 are formed in the first dielectric layer 21, and a plurality of second openings 52 are formed in both the first and second dielectric layers 21 and 22. The second openings 52 are connected to the first openings along the first direction. In some embodiments, the first openings 51 are formed in odd-numbered first segments (i.e., 211, 213 and 215). Additionally, the first openings 51 are formed over odd-numbered protruding portions (i.e., 111, 113 and 115, as shown in FIG. 2). In some embodiments, distances (e.g., D1 and D2) between adjacent first openings 51 along the second direction are substantially equal. In other words, the interval distance DI or D2 between the first openings 51 in the first segment 211, 212, 213, 214, or 215 is substantially consistent along the second direction.

The plurality of second openings 52 are disposed between the first openings 51 along the first direction. In some embodiments, the second openings 52 are formed in even-numbered first segments (i.e., 212 and 214). In some embodiments, the second openings 52 are formed over even-numbered protruding portions (i.e., 112 and 114, as shown in FIG. 2). In some embodiments, the second openings 52 are formed in the second dielectric layer 22. Additionally, in some embodiments, the second openings 52 are formed over the recessed portions 12 shown in FIG. 2. In some embodiments, each second opening 52 connects adjacent first openings 51 along the first direction. Furthermore, in some embodiments, a distance D3 between two adjacent second openings 52 in a first segment 212 or 214 is substantially consistent along the second direction.

A dimension or a size of the second opening 52 may be greater than that of the first opening 51. In some embodiments, a width W51 of the first opening 51 is substantially less than a width W52 of the second opening 52, with both widths measured along the second direction. In some embodiments, a length L51 of the first opening 51 is substantially less than a length L52 of the second opening 52, with both lengths measured along the first direction. Additionally, in some embodiments, the length L52 of the second opening 52 is about three times the length L51 of the first opening 51.

In some embodiments, the first openings 51 serve to define isolations (e.g., 23 in FIG. 25) on the odd-numbered first protruding portions 111, 113 and 115, while the second openings 52 are used to define active areas (e.g., AA in FIG. 25) on the even-numbered first protruding portions 112 and 114. To ensure that the active areas AA are of substantially equal sizes and interlaced along the first direction on different protruding portions 11, the width W52 of the second opening 52 should be substantially equal to the distance D1 or D2 between adjacent first openings 51. Additionally, a distance D3 between adjacent second openings 52 along the second direction should be substantially equal to the width W51 of the first opening 51.

Configurations of the first openings 51 and the second openings 52 from a top view are not limited to those described herein, as long as the aforementioned criteria are met. For example, a configuration of the first openings 51 can be rectangular, as shown in FIG. 26, which illustrates a top view of a stage in the method in accordance with some embodiments of the present disclosure.

Referring back to FIG. 8, in alternative embodiments, each of the first openings 51 can have a dumbbell-like configuration to increase an area of an active area at a concave portion 511 of the first opening 51, in contrast to the embodiments shown in FIG. 26. In some embodiments, the concave portion 511 of the first opening 51 is positioned at or near a central axis of the first segment 211, 213, or 215, with the central axis extending along the second direction.

In some embodiments, each of the second openings 52 can have a regular hexagonal configuration, as shown in FIG. 8. The width W51 of the first opening 51 is measured at the concave portion 511 along the second direction. Similarly, the width W52 of the second opening 52 is measured at a convex portion 521 of the second opening 52 along the second direction. In some embodiments, the convex portion 521 of the second opening 52 is positioned at or near a central axis of the first segment 212 or 214, with the central axis extending along the second direction.

Sidewalls of the first openings 51 and the second openings 52 together define a wavy sidewall S5 extending along the first direction. In some embodiments, a width of the first opening 51 varies along the first direction, with a width W511 or the width W51 representing a minimal width of the first opening 51. Similarly, in some embodiments, a width of the second opening 52 varies along the first direction, with a width W521 or the width W52 representing a maximal width of the second opening 52. Additionally, in some embodiments, a width W512 of the first opening 51 at an interface T2 between the first dielectric layer 21 and the second dielectric layer 22 is substantially less than a width W522 of the second opening 52 at the same interface T2. In other words, a step configuration is defined at a connection between a sidewall S51 of the first opening 51 and a sidewall S52 of the second opening 52. However, the present disclosure is not limited thereto.

In other embodiments, as shown in FIG. 27, each of the second openings 52 can have a hexagonal configuration with varying side lengths. In some embodiments, the width W512 of the first opening 51 at the interface T2 between the first dielectric layer 21 and the second dielectric layer 22 is substantially less than the width W522 of the second opening 52 at the same interface T2. In some embodiments, the sidewall S51 of the first opening 51 and the sidewall S52 of the second opening 52 are smoothly connected. Additionally, in some embodiments, the sidewalls S51 and S52 together define a planar sidewall. Furthermore, in some embodiments, the first and second openings 51 and 52 together have a configuration similar to end-to-end rhombuses.

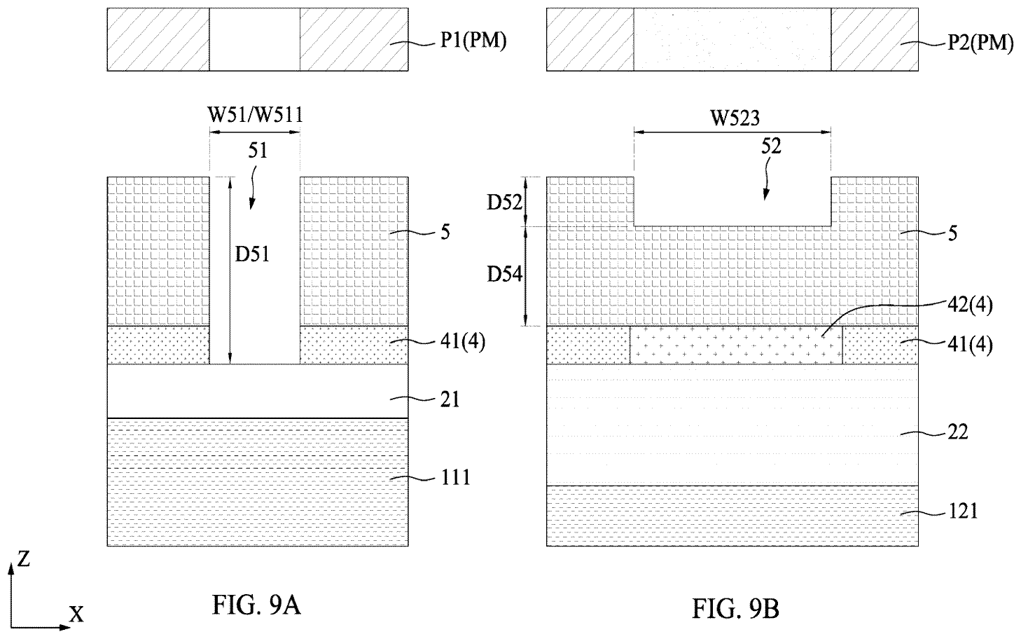

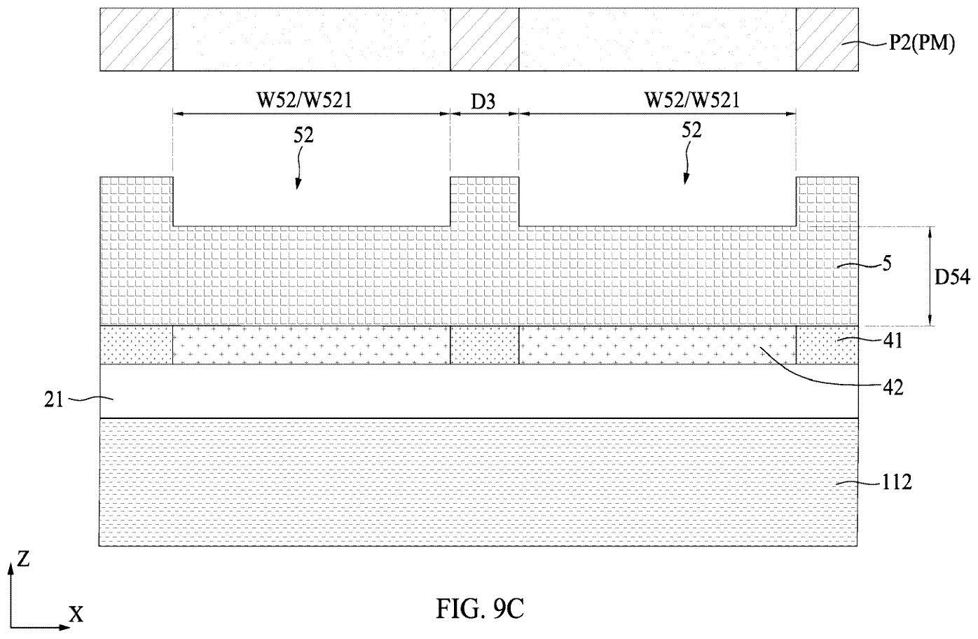

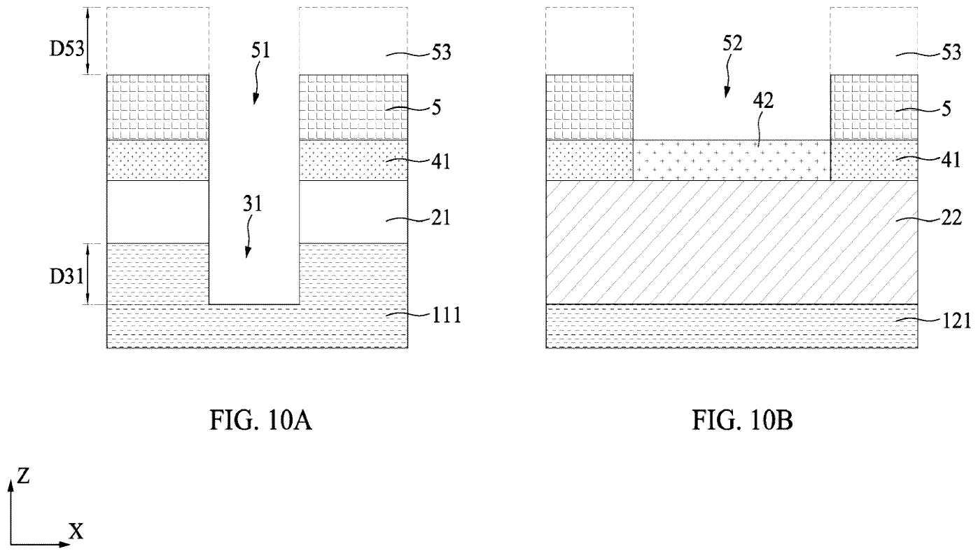

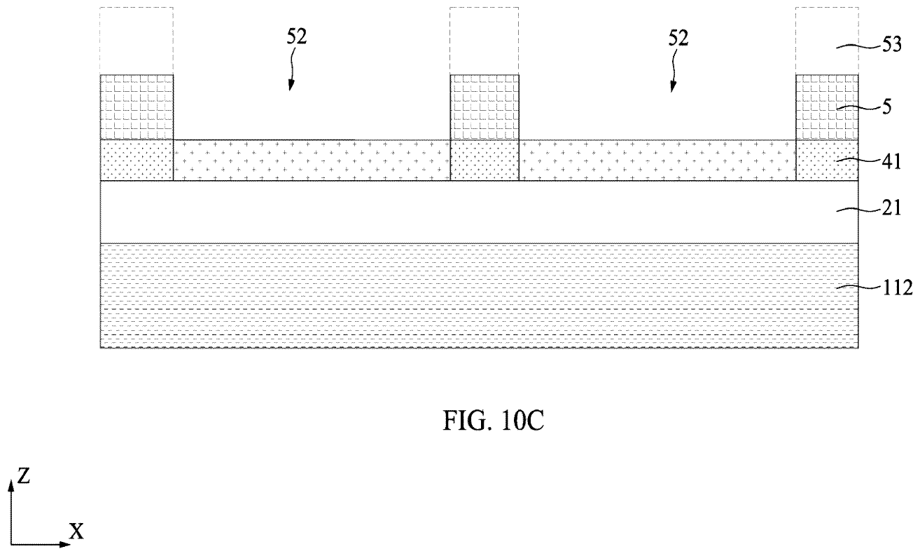

For illustrative purposes, cross-sectional views at different stages of the method are provided in the figures in accordance with some embodiments of the present disclosure. Figures ending with the letter A (e.g., FIG. 9A, FIG. 10A, etc.) indicate cross-sectional views along line A-A′ in FIG. 8 at various stages of the method. Figures ending with the letter B (e.g., FIG. 9B, FIG. 10B, etc.) indicate cross-sectional views along line B-B′ in FIG. 8 at different stages of the method. Similarly, figures ending with the letter C (e.g., FIG. 9C, FIG. 10C, etc.) indicate cross-sectional views along line C-C′ in FIG. 8 at various stages of the method.

With reference to FIGS. 9A, 9B and 9C, cross-sectional views along the lines A-A′, B-B′ and C-C′ in FIG. 8 are presented. In some embodiments, the openings 51 and 52 are defined by a photomask PM. Additionally, in some embodiments, the openings 51 and 52 are formed concurrently through a same patterning operation. In some embodiments, EBL is applied in the patterning operation.

The photomask PM may include different patterns to define the first openings 51 and the second openings 52. In some embodiments, a first pattern P1 of the photomask PM is used to define the first openings 51, while a second pattern P2 is used to define the second openings 52. The first pattern P1 and the second pattern P2 may have different optical transmission rates. In some embodiments, an optical transmission rate of the first pattern P1 is substantially greater than an optical transmission rate of the second pattern P2. In some embodiments, the optical transmission rate of the second pattern P2 is between 1/10 and 9/10 of the optical transmission rate of the first pattern P1. In some embodiments, the optical transmission rate of the first pattern P1 is 100%, while the optical transmission rate of the second pattern P2 is 33.3%.

The formation of the first openings 51 and the second openings 52 can involve multiple operations. In some embodiments, an exposure operation for the photoresist layer 5 is performed using the photomask PM, followed by application of a developer to the photoresist layer 5 to create the first openings 51 and the second openings 52. The first openings 51 having a depth D51 and the second openings 52 having a depth D52 are thus formed, wherein the depth D51 is substantially greater than the depth D52 due to different optical transmission rates of the patterns P1 and P2 of the photomask PM. In some embodiments, the depth D51 of the first openings 51 is substantially equal to a total thickness of the photoresist layer 5 and the first mask layer 4. Additionally, in some embodiments, the depth D52 of the second openings 52 is about 1/10 to 9/10 of the depth D51, depending on the optical transmission rate of the pattern P2. Furthermore, in some embodiments, a thickness D54 of a portion of the photoresist layer 5 remaining under the second openings 52 is greater than zero.

In some embodiments, the first opening 51 penetrates the photoresist layer 5 and the first mask layer 4 due to a high optical transmission rate of the first pattern P1. In some embodiments, the developer removes a portion of the first mask layer 4 that is overlapped by the first opening 51. The second opening 52, in some embodiments, partially penetrates the photoresist layer 5 due to a low optical transmission rate. Additionally, in some embodiments, chemical properties of a portion of the first mask layer 4 overlapped by the second opening 52 are altered due to an optical illumination of the exposure operation during the patterning operation. In some embodiments, the portion of the first mask layer 4 overlapped by the second opening 52 is degraded by the exposure operation, while the photoresist layer 5 is only partially degraded due to a difference in the photosensitivities of the first mask layer 4 and the photoresist layer 5. For ease of description, the degraded portion of the first mask layer 4 is referred to as a second mask layer 42, while a remaining portion of the first mask layer 4 that is free of degradation is referred to as a first mask layer 41. In some embodiments, a width W523 of the second opening 52 shown in FIG. 9B is substantially less than or equal to the width W521 shown in FIG. 9C, depending on the specific applications.

With reference to FIGS. 10A, 10B and 10C, a first recess 31 of the protruding portion 11 is formed under the first opening 51 using the photoresist layer 5 as a mask. In some embodiments, a portion of the first dielectric layer 21 exposed by the first opening 51 is removed using the photoresist layer 5 as a mask. Additionally, in some embodiments, a portion of the protruding portion 11 of the substrate 1 beneath the first opening 51 is partially removed. The removal of the portion of the first dielectric layer 21 and the removal of the portion of the protruding portion 11 can be performed by a same etching operation or by different etching operations, and they are not limited to these methods. In some embodiments, the etching operation includes a dry etching process.

In some embodiments, an etchant in the etching operation exhibits a low selectivity to the second mask layer 42, causing the etching operation to stop at the second mask layer 42. As a result, the portions of the second dielectric layer 22 and the first dielectric layer 21 located beneath the second opening 52 remain intact. A depth D31 of the first recess 31 is typically in a range of 0.1 to 1 μm. In some embodiments, the depth D31 is substantially equal to the depth D12, as shown in FIG. 3. Additionally, a portion 53 of the photoresist layer 5 may be removed during the etching operation, with a thickness of the portion D53 being substantially equal to the thickness D54, as shown in FIGS. 9B and 9C.

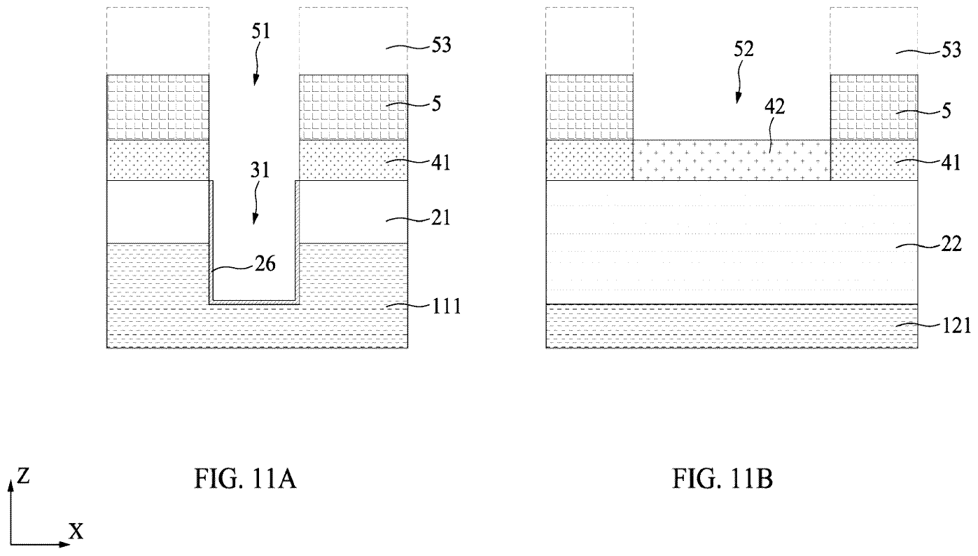

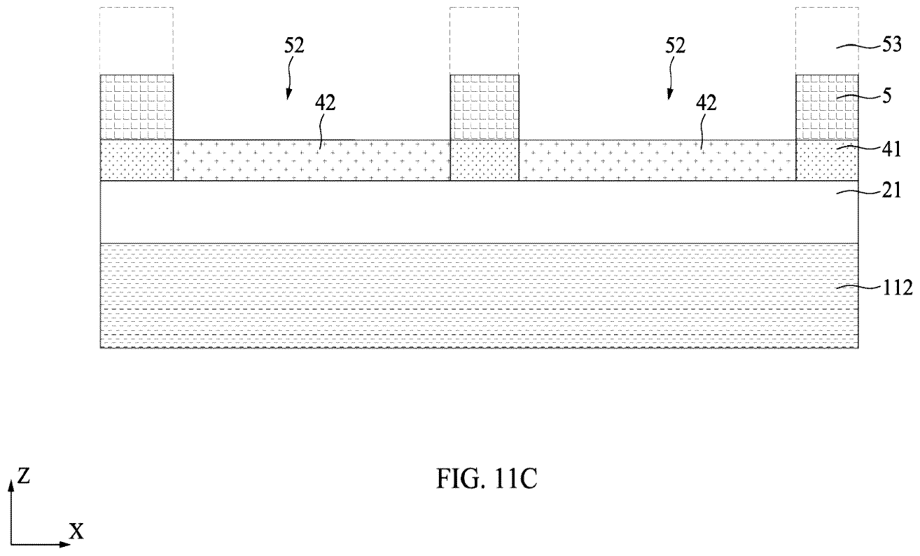

With reference to FIGS. 11A, 11B and 11C, a first conformal layer 26 is formed to line the first recess 31 and the first dielectric layer 21. In some embodiments, the first conformal layer 26 is formed through an oxidation of materials from both the first dielectric layer 21 and the substrate 1. In some embodiments, the first conformal layer 26 includes oxide, with a portion that contacts the substrate 1 consisting of silicon oxide, and a portion that contacts the first dielectric layer 21 comprising oxynitride.

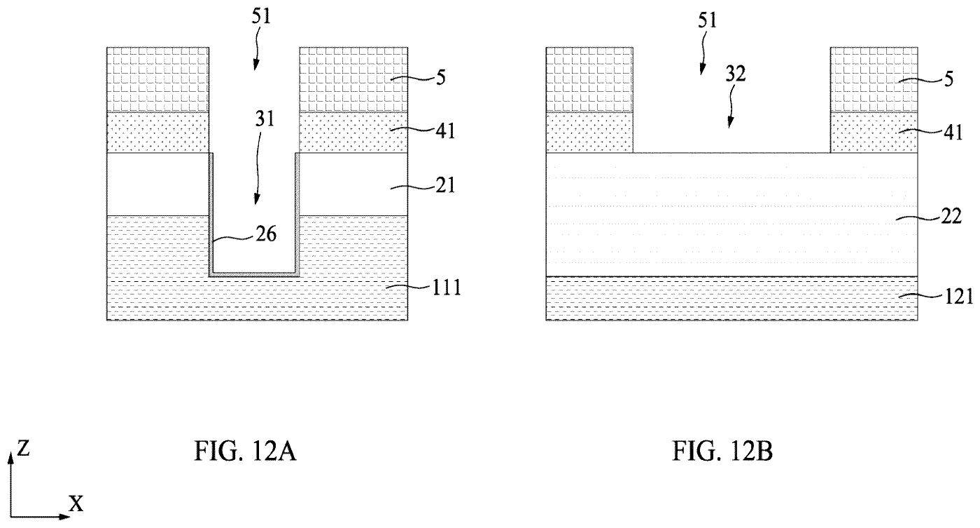

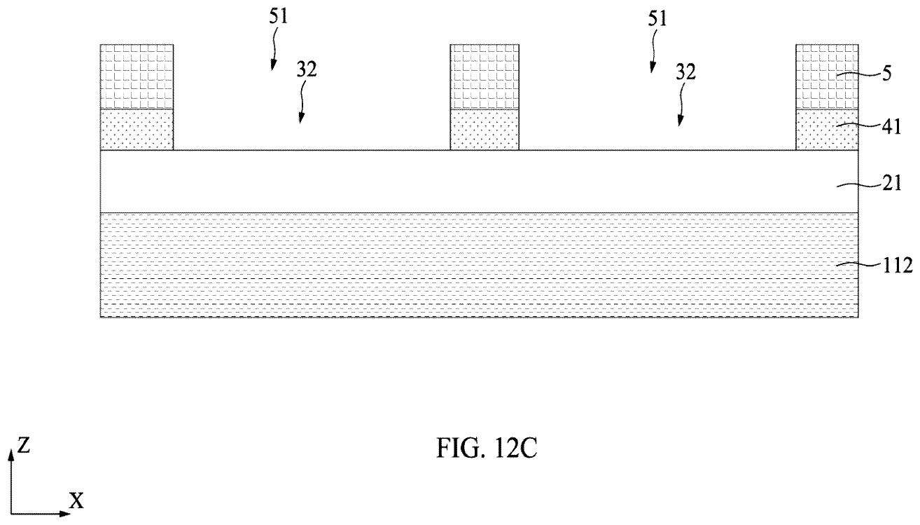

With reference to FIGS. 12A, 12B and 12C, a portion of the second mask layer 42 that is exposed by the second opening 52 is removed, resulting in formation of third openings 32. In some embodiments, the removal of the second mask layer 42 is accomplished using a developer. Additionally, in some embodiments, a sidewall of the first mask layer 41 is aligned with or coplanar with a sidewall of the photoresist layer 5. The third openings 32 are connected to the second openings 52, and in some embodiments, the third openings 32 serve as through holes in the first mask layer 41. Furthermore, as shown in FIG. 12B, the second dielectric layer 22 is partially exposed by the third openings 32, while, as shown in FIG. 12C, the first dielectric layer 21 is partially exposed by the same openings.

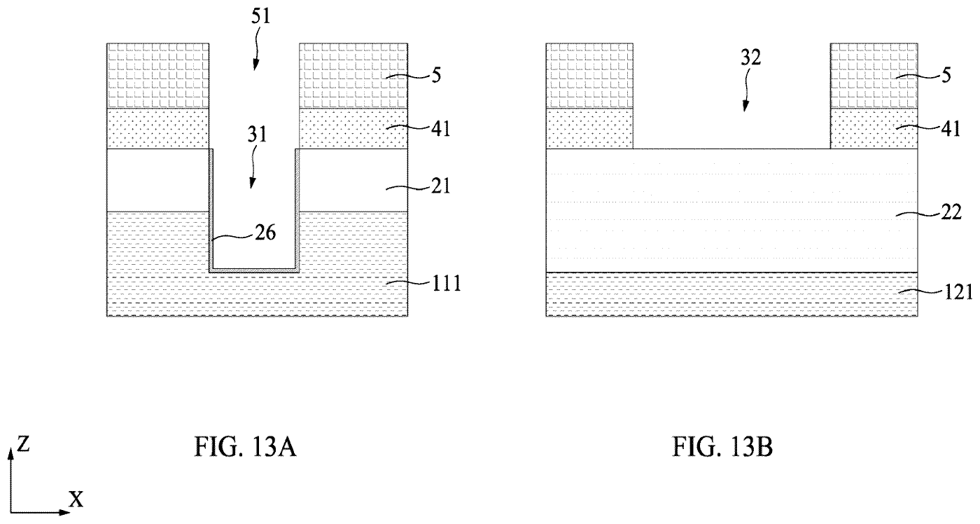

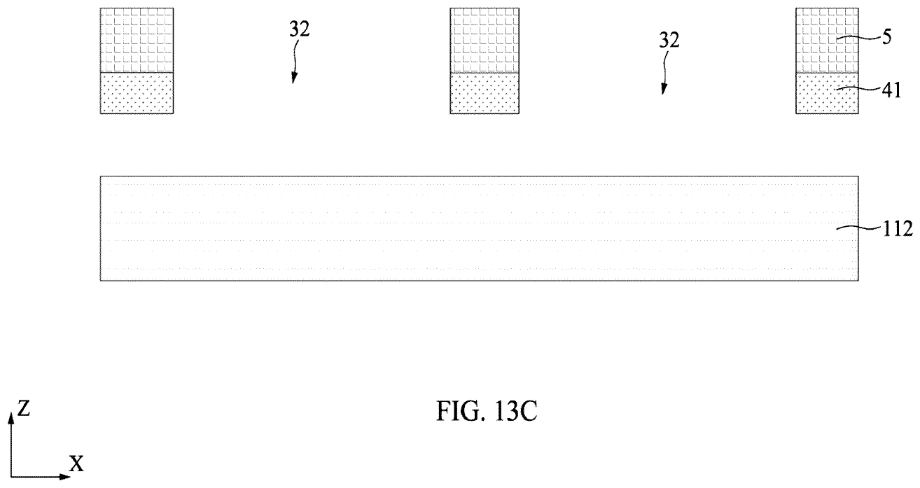

With reference to FIGS. 13A, 13B and 13C, the first dielectric layer 21 is partially removed. In some embodiments, a wet etching operation is performed to remove exposed portions of the first dielectric layer 21. An etchant used in this wet etching operation exhibits a high etch rate selectivity for a material of the first dielectric layer 21 compared to a material of the first conformal layer 26. As a result, the even-numbered first segments (e.g., 212 and 214) of the first dielectric layer 21 are removed due to exposure to the etchant through the third openings 32. Additionally, the even-numbered protruding portions 112 and 114 (as shown in FIG. 2) are exposed to air in the processing chamber following the partial removal of the first dielectric layer 21. In contrast, the odd-numbered first segments (e.g., 211, 213 and 215) of the first dielectric layer 21 remain intact, protected from the etchant by the first conformal layer 26. Furthermore, the second dielectric layer 22 is also preserved due to a high etch rate selectivity of the material of the first dielectric layer 21 relative to a material of the second dielectric layer 22.

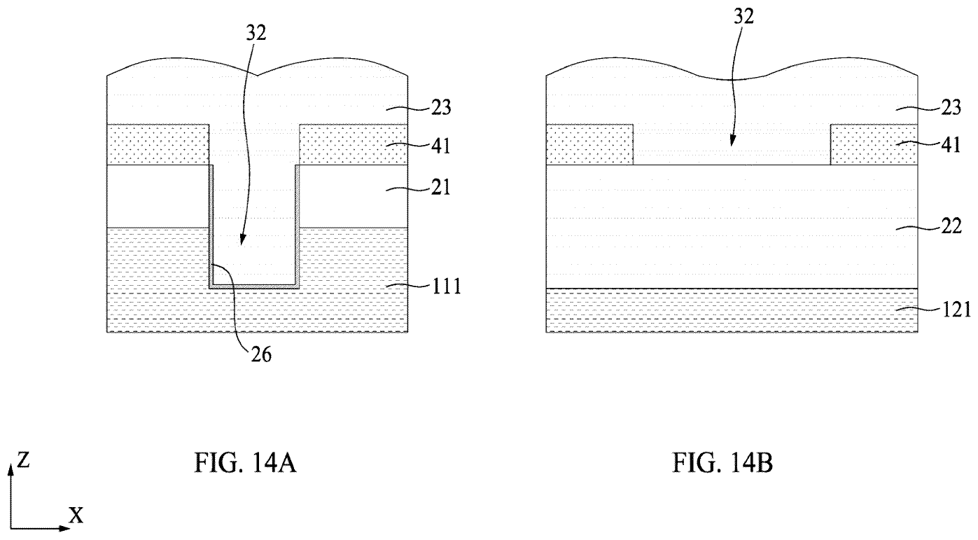

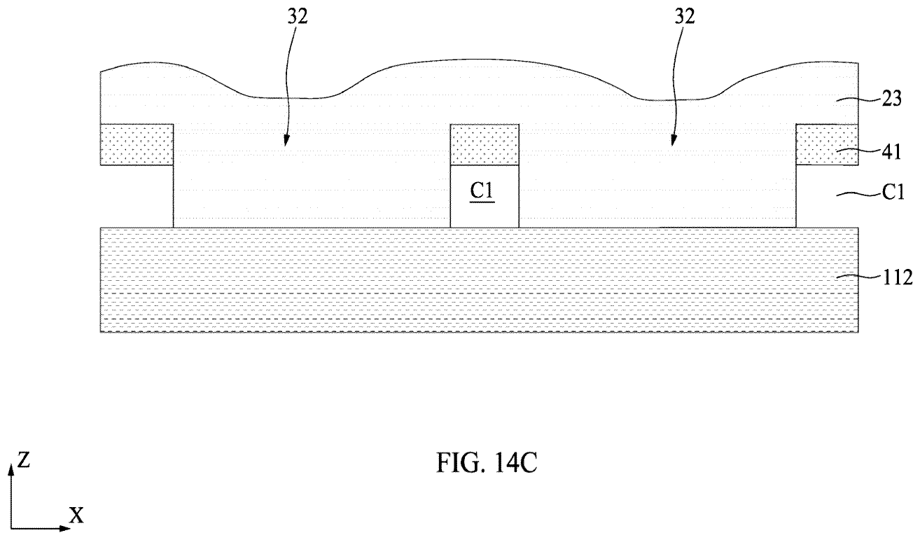

With reference to FIGS. 14A, 14B and 14C, the photoresist layer 5 is removed, and a third dielectric layer 23 is formed over the substrate 1. In some embodiments, a gap fill operation is performed using a deposition. In some embodiments, the deposition includes chemical vapor deposition (CVD), atomic layer deposition (ALD), plasma-enhanced chemical vapor deposition (PECVD), plasma-enhanced atomic layer deposition (PEALD), or a combination thereof.

In some embodiments, the third dielectric layer 23 fills the first recess 31 and an opening in the first mask layer 41 that is positioned over the first recess 31. Additionally, the third dielectric layer 23 may contact the first conformal layer 26. In some embodiments, the third dielectric layer 23 also fills the third opening 32 above the second dielectric layer 22, establishing contact with the second dielectric layer 22. In some embodiments, a dielectric material of the third dielectric layer 23 is same as a dielectric material of the second dielectric layer 22. Furthermore, the third dielectric layer 23 may include oxide.

In some embodiments, the third dielectric layer 23 is positioned directly over portions of the even-numbered protruding portions 112 and 114 (as shown in FIG. 2), wherein the portions of the even-numbered protruding portions 112 and 114 are either overlapped by or vertically exposed through the third openings 32. Due to a property of the deposition process, as illustrated in FIG. 14C, the third dielectric layer 23 does not completely fill a space between the protruding portion 112 and the first mask layer 41. In some embodiments, the third dielectric layer 23 contacts the portion of the protruding portion 112 that is vertically overlapped by the third opening 32, as shown in FIG. 14C. This configuration defines multiple cavities C1, which are bounded by the third dielectric layer 23, the first mask layer 41, and the protruding portion 112 of the substrate 1. Additionally, an excess portion of the third dielectric layer 23 is formed above and covers the first mask layer 41 due to a property of the deposition.

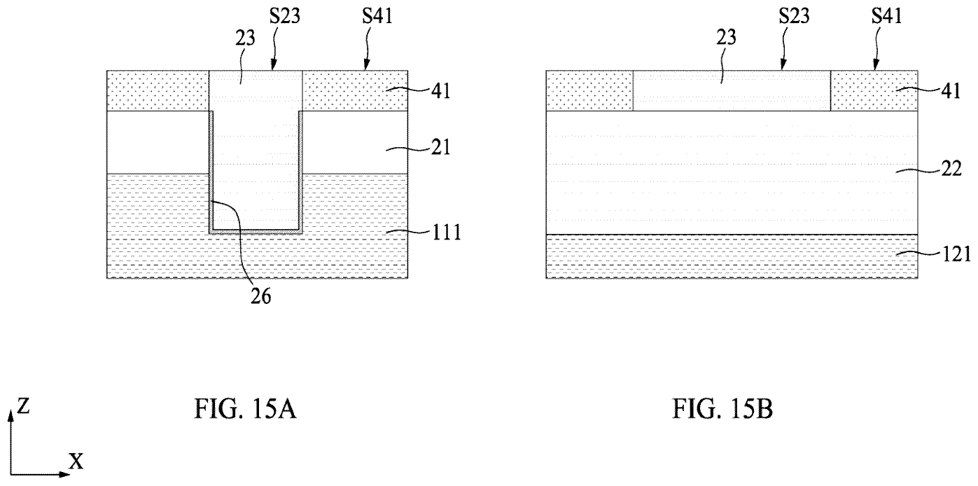

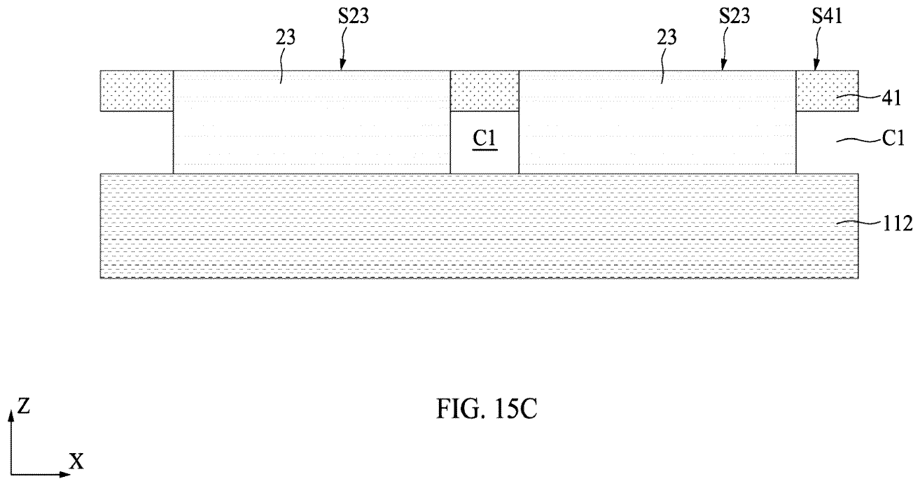

With reference to FIGS. 15A, 15B and 15C, a planarization is performed to remove the excess portion of the third dielectric layer 23 that is above the first mask layer 41. In some embodiments, the planarization includes a chemical mechanical polishing (CMP), a time-mode etching operation, or a combination thereof. The first mask layer 41 serves as a stop layer during the CMP or the etching operation. In some embodiments, a top surface S23 of the third dielectric layer 23 is substantially aligned with or coplanar with a top surface S41 of the first mask layer 41.

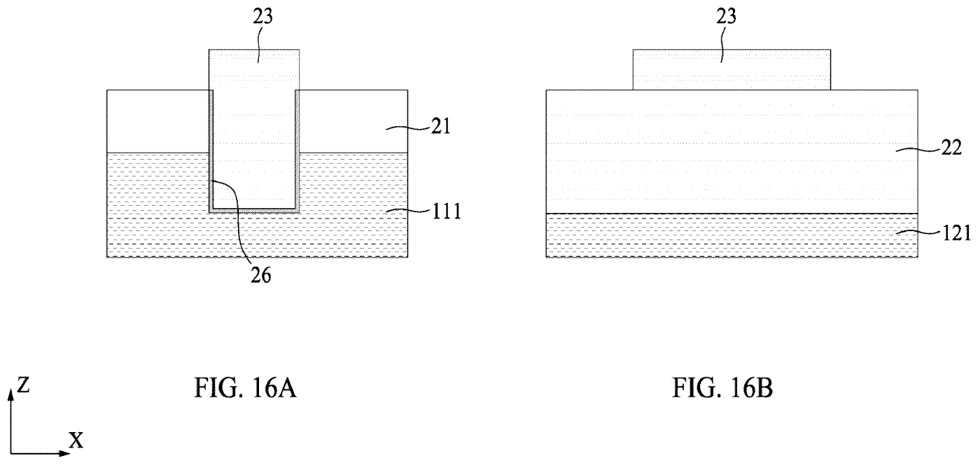

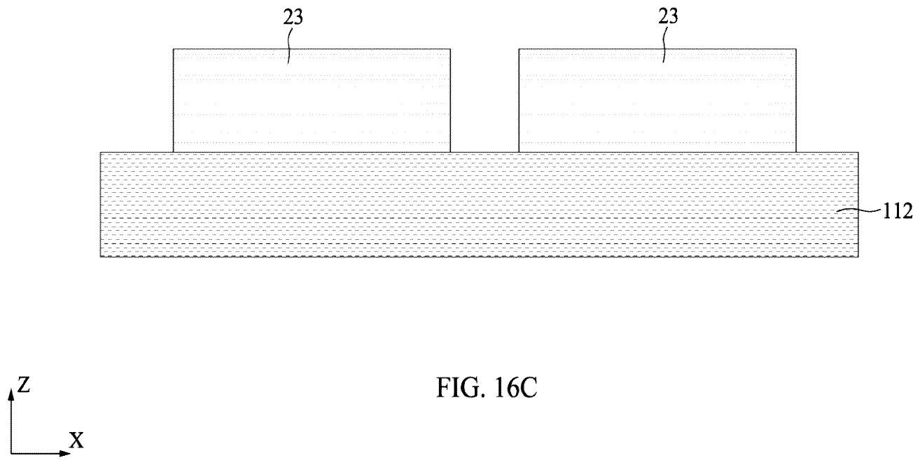

With reference to FIGS. 16A, 16B and 16C, the first mask layer 41 is removed through an etching operation. In some embodiments, the cavities C1 shown in FIG. 15C are revealed or exposed. The odd-numbered protruding portions 111, 113 and 115, as depicted in FIG. 2, are covered by the third dielectric layer 23 and the first dielectric layer 21, as shown in FIG. 16A. The recessed portions 12 from FIG. 2 remain covered by the second dielectric layer 22, while portions of the second dielectric layer 22 within the coverage areas of the second openings 52, as shown in FIG. 8, are covered by the third dielectric layer 23, as illustrated in FIG. 16B. Additionally, portions of the even-numbered protruding portions 112 and 114 within the coverage areas of the second openings 52, shown in FIGS. 2 and 8, are covered by the third dielectric layer 23, as depicted in FIG. 16C. In some embodiments, the remaining portions of the even-numbered protruding portions 112 and 114 that are outside the coverage areas of the second openings 52, as shown in FIGS. 2 and 8, are exposed through the third dielectric layer 23, as illustrated in FIG. 16C.

With reference to FIGS. 17A, 17B and 17C, an etching operation is performed to remove the portions of the protruding portions 11 that are exposed through the third dielectric layer 23. In some embodiments, an etchant used in the etching operation exhibits high selectivity to silicon material. The first dielectric layer 21, the second dielectric layer 22, and the third dielectric layer 23 serve as masks during the etching operation. The etching operation results in formation of multiple second recesses 33. In some embodiments, a depth D33 of the second recess 33 ranges from 0.1 to 1 μm. In some embodiments, the depth D33 is substantially equal to the depth D31 shown in FIG. 10A or the depth D12 shown in FIG. 3.

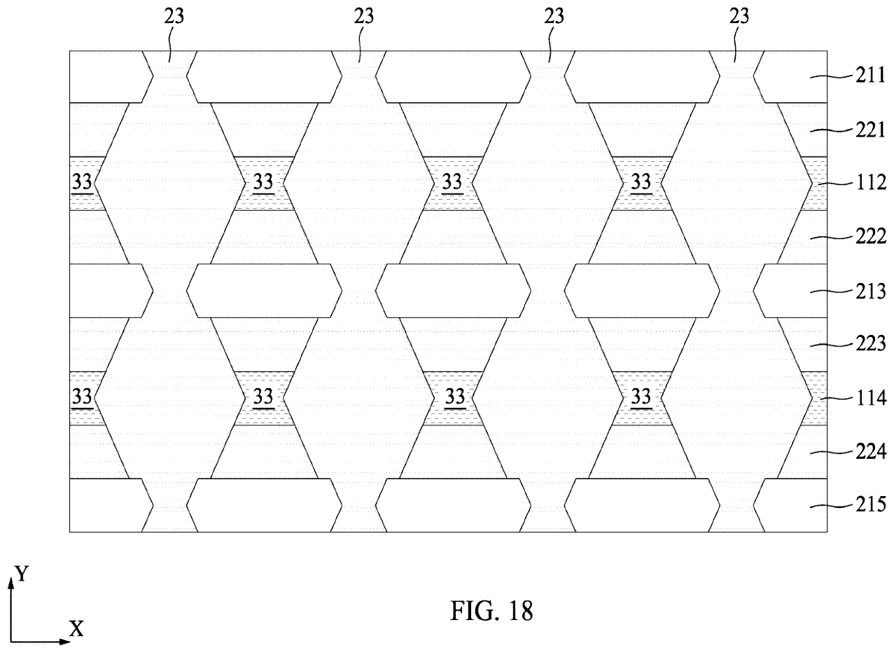

FIG. 18 is a top view of the stage depicted in FIGS. 17A, 17B and 17C of the method described in the present disclosure, in accordance with some embodiments. In some embodiments, the third dielectric layer 23 has a configuration similar to or substantially same as the configurations of the first and second openings 51 and 52 shown in FIG. 8. The odd-numbered first segments 211, 213 and 215 of the first dielectric layer 21 remain intact. Additionally, the first dielectric layer 21 is penetrated by the third dielectric layer 23 at positions of the first openings 51, as shown in FIGS. 8 and 18. Portions of the even-numbered protruding portions 112 and 114 are partially exposed through the third dielectric layer 23. In some embodiments, the second recesses 33 of the protruding portions 112 and 114 are defined by the third dielectric layer 23.

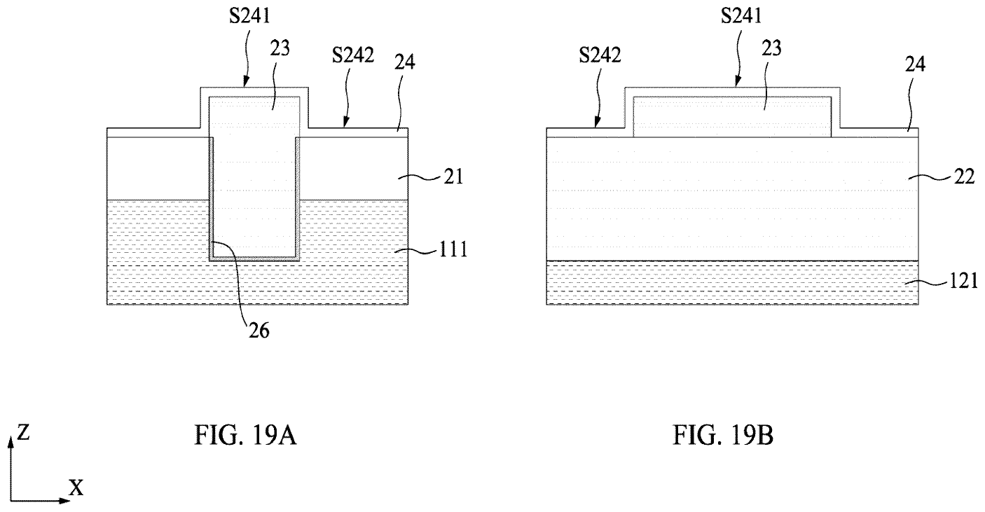

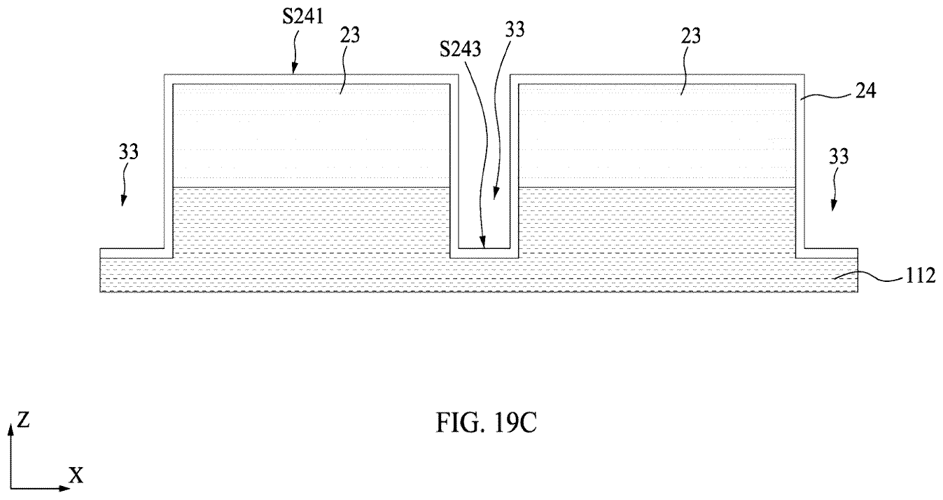

With reference to FIGS. 19A, 19B and 19C, a second conformal layer 24 is formed over the first dielectric layer 21, the second dielectric layer 22, the third dielectric layer 23, and the substrate 1. In some embodiments, the second conformal layer 24 is formed through a conformal deposition, which may include atomic layer deposition (ALD), plasma-enhanced atomic layer deposition (PEALD), or a combination thereof. The second conformal layer 24 may consist of a dielectric material that is similar to or same as a dielectric material of the first dielectric layer 21. In some embodiments, the second conformal layer 24 includes nitride and lines the second recesses 33.

The second conformal layer 24 consists of multiple horizontal portions, as shown in FIGS. 19A, 19B and 19C, which define three horizontal levels. In some embodiments, the first horizontal level S241 is established by the horizontal portions of the second conformal layer 24 that are disposed over the third dielectric layer 23. The second horizontal level S242 is defined by horizontal portions of the second conformal layer 24 located over the first dielectric layer 21 and the second dielectric layer 22. The third horizontal level S243 is defined by the horizontal portions of the second conformal layer 24 situated at a bottom of the recess 33.

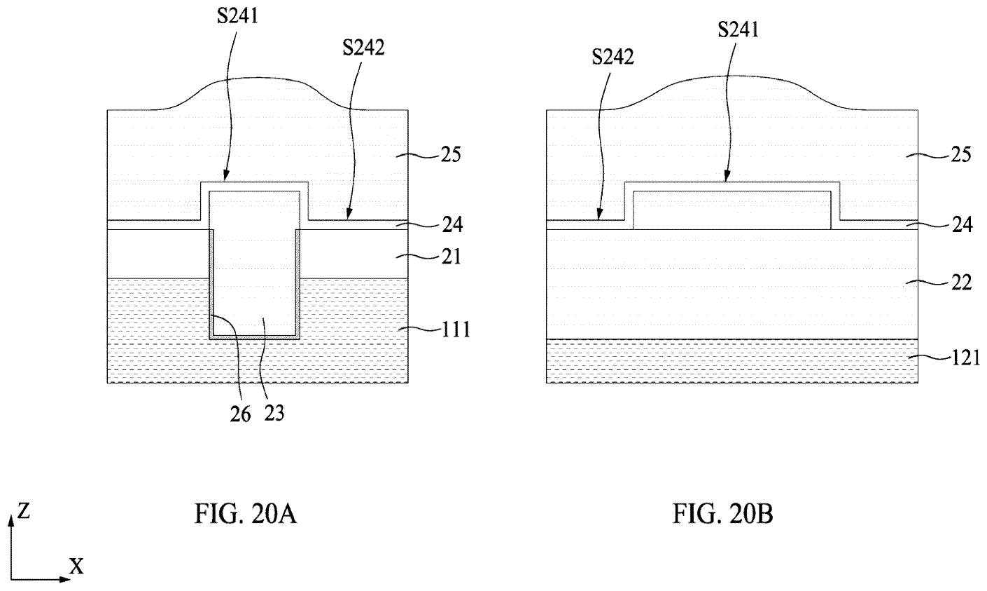

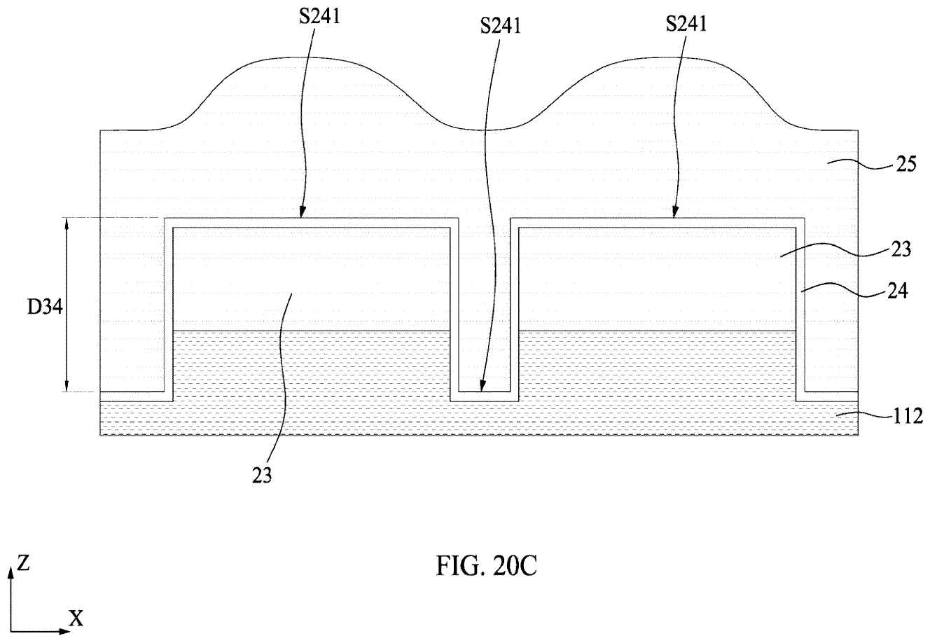

With reference to FIGS. 20A, 20B and 20C, a fourth dielectric layer 25 is formed over the second conformal layer 24. In some embodiments, the fourth dielectric layer 25 is formed through a conformal deposition process, which may include chemical vapor deposition (CVD), atomic layer deposition (ALD), physical vapor deposition (PVD), plasma-enhanced atomic layer deposition (PEALD), or a combination thereof. The fourth dielectric layer 25 may consist of a dielectric material that is similar to or same as a dielectric material of the second dielectric layer 22. In some embodiments, the fourth dielectric layer 25 includes oxide. In some embodiments, the fourth dielectric layer 25 fills the second recess 33. A thickness of the fourth dielectric layer 25 is substantially equal to or greater than a total depth D34, which is the combined thickness of the third dielectric layer 23 and the depth D33 of the recess 33, as shown in FIG. 17C. This ensures that the fourth dielectric layer 25 adequately fills the recesses 33 and the opening in the third dielectric layer 23.

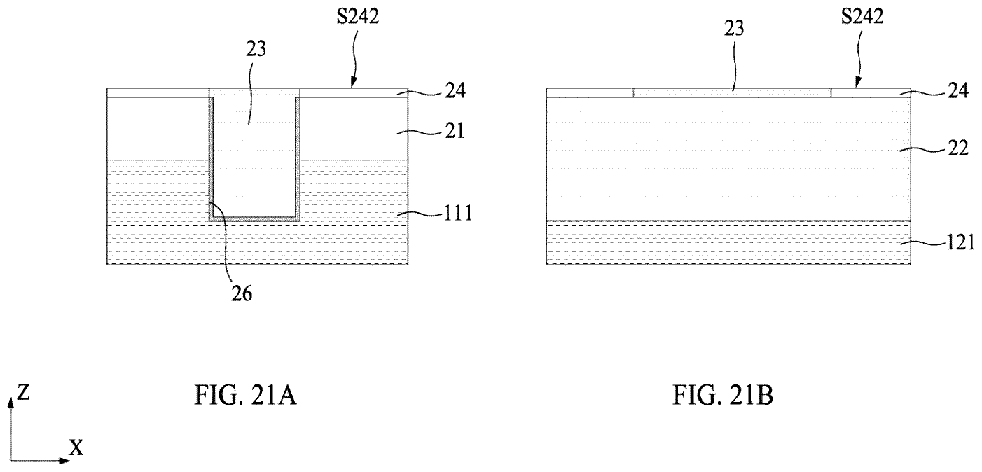

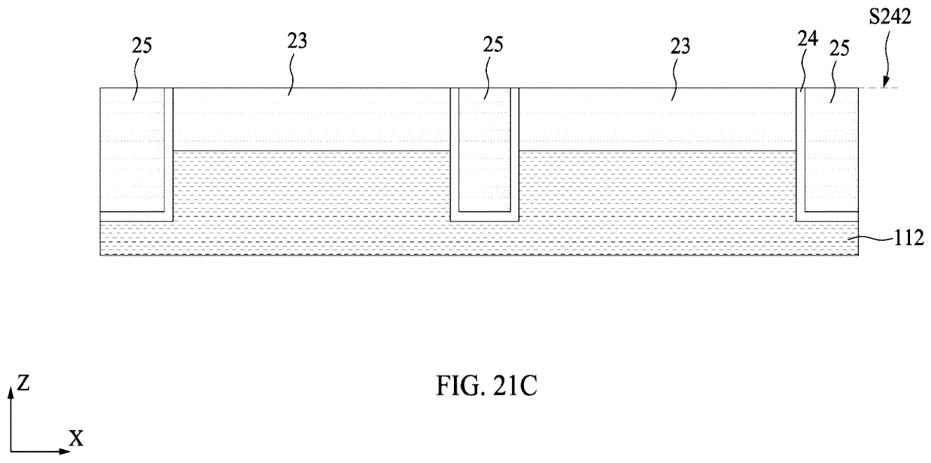

With reference to FIGS. 21A, 21B and 21C, a planarization is performed, stopping at the second horizontal level S242 of the second conformal layer 24. In some embodiments, the planarization may involve chemical mechanical polishing (CMP), an etching operation, or a combination thereof. An etchant used in the etching operation exhibits high selectivity for oxide materials and low selectivity for nitride materials. As a result, the etching operation removes portions of the second conformal layer 24 that are above the second horizontal level S242, due to a small coverage area of the portions of the second conformal layer 24 above the second horizontal level S242. In some embodiments, a ratio of a surface area of the second conformal layer 24 to a surface area of the fourth dielectric layer 25 at the first horizontal level S241, as shown in FIGS. 20A, 20B and 20C, is very small, allowing the etching operation to effectively remove portions of the second conformal layer 24 at the first horizontal level S241. Furthermore, the etching operation can be easily controlled to stop at the second horizontal level S242 because of a high ratio of a surface area of the second conformal layer 24 to a surface area of the fourth dielectric layer 25 at the second horizontal level S242.

With reference to FIGS. 22A, 22B and 22C, the first dielectric layer 21 is removed. In some embodiments, the removal is achieved through an etching operation. An etchant used in the etching operation exhibits a high selectivity for nitride materials. As a result, the second conformal layer 24 remains intact between the third dielectric layer 23 and the fourth dielectric layer 25.

FIG. 23 is a top view of the stage depicted in FIGS. 22A, 22B and 22C of the method described in the present disclosure, in accordance with some embodiments. In some embodiments, the odd-numbered protruding portions 111, 113 and 115 are exposed through the third dielectric layer 23. The second dielectric layer 22 remains over the substrate 1, while the even-numbered protruding portions 112 and 114, as shown in FIG. 2, are covered by both the fourth dielectric layer 25 and the third dielectric layer 23.

With reference to FIGS. 24A, 24B and 24C, the protruding portions 11 are exposed. In some embodiments, portions of the second dielectric layer 22, the third dielectric layer 23, and the fourth dielectric layer 25 are removed to reveal the protruding portions 11. The removal may involve an etching operation, which in some embodiments stops at the top surface S11 of the protruding portions 11. Portions of the third dielectric layer 23 over the odd-numbered protruding portions 111, 113 and 115 are partially removed, as shown in FIG. 24A. In some embodiments, a thickness of the second dielectric layer 22 is reduced to align a top surface of the second dielectric layer 22 with the top surface S11 of the protruding portions 11, as illustrated in FIGS. 24A and 24B. Additionally, portions of the fourth dielectric layer 25 and the second conformal layer 24 above the third recesses 33 are removed. In some embodiments, a top surface S25 of the fourth dielectric layer 25 is substantially aligned with or coplanar with the top surface S11 of the protruding portions 11.

FIG. 25 is a top view of the stage depicted in FIGS. 24A, 24B and 24C of the method described in the present disclosure, in accordance with some embodiments. The exposed portions of the protruding portions 11 become active areas AA of a semiconductor structure. In some embodiments, each active area AA may have a hexagonal configuration. In some embodiments, the third dielectric layer 23 and the fourth dielectric layer 25 serve to provide electrical isolation between adjacent active areas AA along the second direction, while the second dielectric layer 22 provides electrical isolation between the active areas AA along the first direction.

It should be noted that, theoretically, the active areas AA are hexagons with sharp corners. However, in practice, the corners of the hexagons are rounded due to the properties of lithography. The active area AA protrudes toward a concave portion 231 of the third dielectric layer 23 or a concave portion 251 of the fourth dielectric layer 25. The regions of the active area AA that extend toward the concave portion 231 or the concave portion 251 can provide additional surface area for passive elements (e.g., capacitors), wiring, routing, landing pads, or other electrical components.

Furthermore, it is known that electric fields can easily accumulate at corners with sharp angles, and the hexagonal configurations of the active areas can reduce the likelihood of current leakage and the accumulation of electric fields.

The present disclosure provides a method for defining active areas of a semiconductor structure. The method involves formation of a patterned mask layer (e.g., the photoresist layer 5) that features an opening (e.g., the openings 51 and 52) with a wavy sidewall and varying widths along a direction orthogonal to an extending direction of an active area to be formed. By utilizing materials with different photosensitivities, multiple patterning operations can be performed on different materials, allowing for the definition of active areas in different rows through distinct patterning processes.

To conclude the operations illustrated in FIGS. 1 to 25 above, methods S10, S20 and S30, which are based on a same concept of the present disclosure, are provided.

FIG. 28 is a flow diagram illustrating a method S10 for manufacturing a semiconductor structure in accordance with some embodiments of the present disclosure. The method S10 includes a number of operations (S101, S102, S103, S104, S105, S106 and S107) and the description and illustration are not deemed as a limitation to the sequence of the operations. In the operation S101, a first mask layer 4 is formed over a substrate 1. In the operation S102, a photoresist layer 5 is formed over the first mask layer 4, wherein a photosensitivity of the photoresist layer 5 is different from a photosensitivity of the first mask layer 4. In the operation S103, a first opening 51 and a second opening 52 are formed, wherein the first opening 51 penetrates the photoresist layer 5 and the first mask layer 4, the second opening 52 partially penetrates the photoresist layer 5, and a portion of the first mask layer 4 overlapped by the second opening 52 is degraded to form a second mask layer 42. In the operation S104, a portion of the substrate 1 exposed by the first opening 51 is partially removed to form a first recess 31 of the substrate 1. In the operation S105, the second mask layer 42 is removed to form a third opening 32 through the first mask layer 4. In the operation S106, a first dielectric layer (e.g., the third dielectric layer 23) is formed, wherein the first dielectric layer fills the first recess 31 and the third opening 32 and covers a portion of the substrate 1 overlapped by the third opening 32. In the operation S107, a patterning operation is performed on the substrate 1 using the first dielectric layer as a mask, and a second recess 33 of the substrate 1 is thereby formed.

FIG. 29 is a flow diagram illustrating a method S20 for manufacturing a semiconductor structure in accordance with some embodiments of the present disclosure. The method S20 includes a number of operations (S201, S202, S203, S204, S205, S206 and S207) and the description and illustration are not deemed as a limitation to the sequence of the operations. In the operation S201, a substrate 1 is provided, wherein the substrate includes a first protruding portion 111 and a second protruding portion 112 substantially parallel to each other and extending along a first direction Y. In the operation S202, the first protruding portion 111 and the second protruding portion 112 are covered by a first dielectric layer 21. In the operation S203, a first mask layer 4 is formed over the first dielectric layer 21, and a photoresist layer 5 is formed over the first mask layer 4. In the operation S204, a patterning operation is performed, wherein a first opening 51 is formed in the first mask layer 4 and the photoresist layer 5 over the first protruding portion 111 and exposing the first dielectric layer 21, and a second opening 52 is formed partially through the photoresist layer 5 over the second protruding portion 112. In the operation S205, a chemical property of a portion of the first mask layer 4 overlapped by the second opening 52 is changed during the patterning operation, and a second mask layer 42 overlapped by the second opening 52 is thereby defined. In the operation S206, a first recess 31 of the first protruding portion 111 is formed using the photoresist layer 5 as a mask. In the operation S207, a portion of the second protruding portion 112 not overlapped by the second mask layer 42 is partially removed, and a second recess 33 of the second protruding portion 112 is thereby formed.

FIG. 30 is a flow diagram illustrating a method S30 for manufacturing a semiconductor structure in accordance with some embodiments of the present disclosure. The method S30 includes a number of operations (S301, S302, S303, S304, S305, S306 and S307) and the description and illustration are not deemed as a limitation to the sequence of the operations. In the operation S301, a substrate 1 is provided, wherein the substrate 1 includes a first protruding portion 111 and a second protruding portion 112, and the first and second protruding portions 111, 112 extend along a first direction Y. In the operation S302, a patterned photosensitive layer (e.g. the first mask layer 4 and the photoresist layer 5) is formed, wherein the patterned photosensitive layer includes a first through hole (e.g., the first opening 51) over the first protruding portion 111 and a recess (second opening 52) over the second protruding portion 112, wherein the first through hole and the recess are connected along a second direction X substantially orthogonal to the first direction Y, and a width W51 of the first through hole is less than a width W52 of the recess. In the operation S303, a portion of the substrate exposed by the first through hole is partially removed, and a first opening (e.g., the first recess 31) of the substrate 1 is thereby formed. In the operation S304, a first dielectric layer (e.g., the first conformal layer 26) lining the first opening is formed. In the operation S305, a portion of the patterned photosensitive layer below the recess is partially removed, and a second through hole (e.g., the third openings 32) is thereby formed. In the operation S306, a second dielectric layer (e.g., the third dielectric layer 23) surrounded by the first dielectric layer and disposed within the second through hole is formed. In the operation S307, the substrate 1 is patterned using the second dielectric layer as a mask.

It should be noted that the operations of the method S10, the method S20, and/or the method S30 may be rearranged or otherwise modified within the scope of the various aspects. Additional processes may be provided before, during, and after the method S10, the method S20 and/or the method S30, and some other processes may be only briefly described herein. Thus, other implementations are possible within the scope of the various aspects described herein.

In some embodiments, the active areas AA of the semiconductor structures shown in FIG. 25, FIGS. 26 and 27 are configured to serve as portions of capacitors. In some embodiments, the semiconductor structures include capacitor landing pads 310, as illustrated in FIG. 39.

FIGS. 31 to 39 are schematic cross-sectional diagrams along the line C-C′ in FIG. 8 in accordance with some embodiments of the present disclosure.

In some embodiments, the capacitor landing pads 310 are positioned over the active areas AA, which may be located between the third dielectric layer 23 and/or the fourth dielectric layer 25. However, for the sake of brevity, the cross-sectional diagrams shown in FIGS. 31 to 39 are depicted only along the line C-C′ in FIG. 8, specifically illustrating the active areas AA between the fourth dielectric layer 25.

With reference to FIG. 31, a first insulating film 301 and a second insulating film 303 are disposed over the second protruding portion 112, with the second insulating film 303 placed on top of the first insulating film 301. In some embodiments, the first insulating film 301 covers an entire top surface of the second protruding portion 112, the fourth dielectric layer 25, and the second conformal layer 24. After the deposition of first insulating film 301 and the second insulating film 303 is performed, the top surface of the S11 of the protruding portions 112 and the top surface S25 of the fourth dielectric layer 25 are both covered.

The first insulating film 301 may be formed of, for example, silicon nitride, silicon oxide, silicon oxynitride, undoped silica glass, borosilica glass, phosphosilica glass, borophosphosilica glass, or a combination thereof, but is not limited thereto. The second insulating film 303 may be formed of a material same as the material of the first insulating film 301, but is not limited thereto.

With reference to FIG. 32, a third insulating film 305 may be formed on the second insulating film 303. The third insulating film 305 may be formed of a material same as the material of the first insulating film 301, but is not limited thereto. A photolithography process may be used to pattern the third insulating film 305, defining positions of a plurality of contact holes 402, and an etch process may be performed to form the plurality of contact holes 402, which penetrate through the third insulating film 305, the second insulating film 303, and the first insulating film 301. In some embodiments, the contact holes 402 are considered deep holes. After the etch process is performed, a portion of the top surface S11 of the protruding portions 11 is exposed, while the entire top surface S25 of the fourth dielectric layer 25 remains still covered.

With reference to FIG. 33, the contact holes 402 may be filled with material using processes such as chemical vapor deposition, physical vapor deposition, sputtering, or the like. The contact holes 402 may be partially filled with a filling material 402-1. In some embodiments, an upper portion of the contact holes 402 in the third insulating film 305 remains unfilled by the filling material 402-1. In other words, when the material is introduced into the contact holes 402, a top surface of the filling material is coplanar with a top surface of the second insulating film 303.

With reference to FIG. 34, an isotropic etch process may be performed to remove a portion of the third insulating film 305 around the contact holes 402, forming a plurality of transformed holes 404 that consist of a narrow portion 403-1, occupied by the filling material 402-1 in the second insulating film 303, and a wide portion 403-2 in the third insulating film 305. In some embodiments, the narrow portion 403-1 is referred to as the neck portion 403-1, while the wide portion 403-2 is referred to as the head portion 403-2.

With reference to FIG. 35, a conductive material, for example, aluminum, copper, tungsten, cobalt, or other suitable metal or metal alloy is deposited, by a metallization process such as chemical vapor deposition, physical vapor deposition, sputtering, or the like, in the transformed holes 404 to form a plurality of capacitor contacts 403. A planarization process, such as chemical mechanical polishing, may be performed after the metallization process to remove excess deposited material and provide a substantially flat surface for subsequent processing steps.

In some embodiments, each of the capacitor contacts 403 includes a neck portion 403-1 and a head portion 403-2 positioned over the neck portion 403-1, wherein an upper width L1 of the head portion 403-2 is greater than an upper width L2 of the neck portion 403-1. Additionally, the upper width L2 of the neck portion 403-1 is substantially same as a bottom width of the head portion 403-2. In some embodiments, the head portion 403-2 features a curved sidewall 403-3 and may have a tapered profile.

With reference to FIG. 36, a fourth insulating film 307 may be formed on the third insulating film 305. The fourth insulating film 307 may be formed of a material same as the material of the first insulating film 301, but is not limited thereto. A photolithography process may be used to pattern the fourth insulating film 307, defining positions of a plurality of capacitor plugs 411. After the photolithography process is performed, an etch process, such as an anisotropic dry etch process, may be performed to form a plurality of plug openings over the head portion 403-2 and passing through the fourth insulating film 307. A plurality of barrier layers 412 may be disposed in the plug openings, adhering to sidewalls of the plug openings. A conductive material, such as aluminum, copper, tungsten, cobalt, or other suitable metal or metal alloy is deposited in the plug openings through a metallization process, which may include a chemical vapor deposition, a physical vapor deposition, a sputtering, or the like, to form the plurality of capacitor plugs 411. As shown in FIG. 36, the barrier layers 412 are attached to sidewalls 411S of the capacitor plug 411. A planarization process, such as chemical mechanical polishing, may be performed after the metallization process to remove excess deposited material and provide a substantially flat surface for subsequent processing steps.

With reference to FIG. 37, an etch-back process is performed to remove a top portion of the fourth insulating film 307 to expose a protruding portion 411A of the capacitor plug 411 and a top portion 412A of the barrier layer 412. In some embodiments, after the etch-back process is performed, a top surface of the capacitor plug 411 is higher than a top surface 307S of the fourth insulating film 307, and a sidewall of the top portion 412A is exposed.

With reference to FIG. 38, a deposition process is performed to form a liner layer 308, which covers the top surface 307S of the fourth insulating film 307, a top surface of the protruding portion 411A, and the sidewall of the top portion 412A. In some embodiments, the liner layer 308 is a silicon-containing layer, such as a polysilicon layer.

With reference to FIG. 39, a salicidation process (thermal process) is performed to form a plurality of landing pads 310 over the third insulating film 305. Each landing pad 310 includes the protruding portion 411A of the capacitor plug 411, the top portion 412A of the barrier layer 412, a first silicide layer (metal silicide) 308A over the protruding portion 411A, and a second silicide layer (metal silicide) 308B on a sidewall 412AS of the protruding portion 411A. In some embodiments, the thermal process transforms a portion of the protruding portion 411A and the liner layer 308 into the first silicide layer 308A, while the top portion 412A of the barrier layers 412 and the liner layer 308 are transformed into the second silicide layer 308B. Thus, the landing pad 310 is formed without using a lithographic technique, making the landing pad 310 self-aligned to the capacitor plug 411. In some embodiments, a thickness and a shape of the protruding portion 411A and the top portion 412A may be altered (not shown in the drawings).

Since the first silicide layer 308A is sandwiched between the second silicide layers 308B, the first silicide layer 308A is referred to as an inner silicide layer 308A, and the second silicide layer 308B is referred to as an outer silicide layer 308B.

In some embodiments, an etching process, such as an anisotropic dry etching process, is performed to remove a portion of the liner layer 308 that was not transformed into the metal silicide during the thermal process. In other words, the first silicide layer 308A and the second silicide layer 308B are composed of different materials. A process speed of the salicidation process is greater for the top portion 412A compared to the protruding portion 411A, resulting in a top end of the second silicide layer 308B being higher than a top end of the first silicide layer 308A, thereby forming a step structure between the first silicide layer 308A and the second silicide layer 308B. Specifically, a height H2 of the second silicide layer 308B is greater than a height H1 of the first silicide layer 308A. The height H1 and the height H2 are measured along the Z direction, with the height H1 defined as the distance from the top surface of the fourth insulating film 307 to the top end of the first silicide layer 308A. In some embodiments, the second silicide layer 308B surrounds the first silicide layer 308A, and a width L4 of the second silicide layer 308B is greater than a width L3 of the first silicide layer 308A.

As illustrated in FIG. 39, a top corner of the second silicide layer 308B that is distal from the first silicide layer 308A is etched to be a curved sidewall, in contrast to a top corner of the second silicide layer 308B that is proximate to the first silicide layer 308A. In other words, the second silicide layer 308B has rounded outside corners.

In some embodiments, in addition to the capacitor landing pads, the semiconductor structures shown in FIG. 25, FIG. 26 and FIG. 27 further include metal plugs 507 positioned over the capacitor landing pads 310, as illustrated in FIG. 46.

FIGS. 40 to 46 are schematic cross-sectional diagrams along the line C-C′ in FIG. 8, in accordance with some embodiments of the present disclosure.

As mentioned above, the capacitor landing pads 310 are disposed over the active areas AA, which may be disposed between the third dielectric layer 23 and/or between the fourth dielectric layer 25. Consequently, the metal plugs 507 disposed over the capacitor landing pads 310 may also be disposed between the third dielectric layer 23 and/or between the fourth dielectric layer 25. However, for brevity, the cross-sectional diagrams shown in FIGS. 40 to 46 are depicted along the line C-C′ in FIG. 8, specifically illustrating the active areas AA between the fourth dielectric layers 25.

With reference to FIG. 40, a patterned mask 501 is formed over the fourth insulating film 307, covering both the first silicide layer 308A and the second silicide layer 308B.

With reference to FIG. 41, a planarization process is performed on the patterned mask 501. In some embodiments, the planarization process is performed until the second silicide layer 308B is exposed. The planarization process may include a chemical mechanical polishing (CMP) process, which removes excess portions of the patterned mask 501 over the second silicide layer 308B. In some embodiments, the second silicide layer 308B may be slightly etched; however, a topmost surface of the second silicide layer 308B remains higher than a top surface of the first silicide layer 308A. A portion of the patterned mask 501 remains on the first silicide layer 308A, sandwiched by the second silicide layers 308B.

With reference to FIG. 42, a dielectric layer 503 is formed over a remaining portion of the patterned mask 501. With reference to FIG. 43, another patterned mask 505 is formed over the dielectric layer 503. With reference to FIG. 44, the dielectric layer 503 is etched using the patterned mask 505 as a mask, resulting in an opening 510 that penetrates through the dielectric layer 503.

In some embodiments, a portion of the patterned mask 501 over the first silicide layer 308A is removed, exposing the top surface of the first silicide layer 308A. Additionally, the second silicide layer 308B may be slightly etched during the etching process that forms the opening 510. The opening 510 may be formed using a wet etching process, a dry etching process, or a combination thereof.

With reference to FIG. 45, a metal layer 507 is formed over the current structure and deposited in the opening 510. In some embodiments, the metal layer 507 is made of tungsten (W), aluminum (Al), copper (Cu), titanium (Ti), tantalum (Ta), another applicable metal material, or a combination thereof. The formation of the metal layer 507 may include a deposition process, such as a CVD process, a PVD process, an ALD process, an MOCVD process, a sputtering process, a plating process, or another applicable process. In some embodiments, the metal layer 507 covers a top surface of the patterned mask 505.

With reference to FIG. 46, a planarization process is performed to remove the patterned mask 505 and a portion of the metal layer 507, exposing a top surface of the dielectric layer 503. After the planarization process is performed, the dielectric layer 503 and the remaining metal layer 507 are coplanar. In some embodiments, the planarization process includes a chemical mechanical polishing (CMP) process. In some embodiments, the remaining metal layer 507 is referred to as the metal plug 507.

As illustrated in FIG. 46, the metal plug 507 extends into the patterned mask 501, resulting in a bottommost surface of the metal plug 507 being lower than a top surface of the second silicide layer 308B. Furthermore, a width L5 of the metal plug 507 in the dielectric layer 503 is greater than a width L6 of the first silicide layer 308A along the X direction, ensuring that the first silicide layer 308A is entirely covered by the metal plug 507.

FIGS. 47 to 53 are schematic cross-sectional diagrams along the line C-C′ in FIG. 8 in accordance with various embodiments of the present disclosure. Elements in FIGS. 47 to 53 that are same as or similar to elements mentioned above are marked with similar reference numbers and duplicative descriptions are omitted.

With reference to FIG. 47, a substrate 1 (e.g., the protruding portion 112) may be provided. An active area AA, a plurality of first dielectric structures 25, and a conformal layer 24 may be formed in the substrate 1, and a first insulating film 301 may be formed over the substrate 1. The active area AA, the first dielectric structures 25, the conformal layer 24 and first insulating film 301 are respectively same as or similar to the active area AA, the fourth dielectric layer 25, the second conformal layer 24, and the first insulating film 301 mentioned above, and repeated descriptions are omitted.

With reference to FIG. 47, a plurality of word lines 302 may be disposed in the active area AA and surrounded by the first insulating film 301. The word lines 302 may be respectively located in a plurality of trenches TR wherein the trenches TR are disposed in the first insulating film 301 and extend into the substrate 1. Each of the word lines 302 may include a word line channel film 302-1, a word line insulating film 302-3, and a word line electrode 302-5. The word line channel film 302-1 may be disposed on a sidewall TR-S of the trench TR and inwardly positioned within the first insulating film 301 and the substrate 1. In some embodiments, a lower portion 302-1L of the word line channel film 302-1 penetrates an upper portion 1U of the substrate 1, while an upper portion 302-1U of the word line channel film 302-1 is positioned in the first insulating film 301. The word line electrode 302-5 may be disposed over and surrounded by the word line channel film 302-1. The word line insulating film 302-3 may be conformally disposed between the word line channel film 302-1 and the word line electrode 302-5.

A deposition method, such as chemical vapor deposition (CVD), may be sequentially performed to conformally deposit the word line channel film 302-1 and the word line insulating film 302-3 over the sidewall TR-S of the trench TR, and to fill the trench TR with the word line electrode 302-5. In some embodiments, after the deposition method is performed, a planarization process is conducted to remove portions of the word line channel film 302-1, the word line insulating film 302-3, and the word line electrode 302-5 over the top surface 301T of the first insulating film 301, providing a substantially flat surface for subsequent processing steps.

In some embodiments, the word line channel film 302-1 may be formed of, for example, doped polysilicon or undoped polysilicon. Doped polysilicon may be doped with a dopant such as phosphorus, arsenic, or antimony. In some embodiments, the word line insulating film 302-3 may be formed of, for example, an insulating material having a dielectric constant of about 4.0 or greater. Alternatively, in another embodiment, the insulating material may be silicon oxide, silicon nitride, silicon oxynitride, silicon nitride oxide, or the like. In some embodiments, the plurality of word line electrodes 302-5 may be formed of, for example, a conductive material such as doped polysilicon, silicon germanium, metal, metal alloy, metal silicide, metal nitride, metal carbide, or a combination including multilayers thereof. The metal may be aluminum, copper, tungsten, or cobalt. The metal silicide may be nickel silicide, platinum silicide, titanium silicide, molybdenum silicide, cobalt silicide, tantalum silicide, tungsten silicide, or the like.

Additionally, in some embodiments, the word line channel film 302-1, the word line insulating film 302-3, and the word line electrode 302-5 may function as a work-function adjustment mechanism. In such embodiments, the word line channel film 302-1 may serve as a source layer, the word line electrode 302-5 may serve as a conductive layer, and the word line insulating film 302-3 may serve as a work-function adjustment layer.

In such embodiments, the source layer 302-1 may include a work-function adjustment element or a compound of the work-function adjustment element. For example, the work-function adjustment element may include a metal such as lanthanum, strontium, antimony, yttrium, aluminum, tantalum, hafnium, iridium, zirconium, or magnesium. The conductive layer 302-5 may include a metal such as tungsten, titanium, or tantalum. A thermal treatment process (e.g., an annealing process) may be performed to allow the work-function adjustment element to diffuse into the work-function adjustment layer 302-3.

With reference to FIG. 48, a first part 304-3 of a bit line contact BC (see FIG. 53) may be formed over the substrate 1. The first part 304-3 of the bit line contact BC may be disposed in an opening 304-7 that is located within the first insulating film 301 and the second insulating film 303. In addition, a first spacer 306-3′ may be disposed on a sidewall of the opening 304-7, and a second spacer 306-7 may be positioned between the first spacer 306-3′ and the first part 304-3 of the bit line contact BC. A first liner 306-5 may be conformally disposed on the first part 304-3 of the bit line contact BC, positioned between the second spacer 306-7 and the bit line contact 304-3, and between the first part 304-3 and the substrate 1. In some embodiments, a top surface 304-3T of the first part 304-3 of the bit line contact BC is coplanar with a top surface 303T of the second insulating film 303. In some embodiments, a bottom surface 304-3B of the first part 304-3 of the bit line contact BC is positioned higher than a bottom surface 301B of the first insulating film 301.

A deposition process, such as chemical vapor deposition (CVD), may be sequentially performed, followed by an etching process, such as an anisotropic etching process, to form the first spacer 306-3′ and the second spacer 306-7. Subsequently, the first liner 306-5 may be conformally formed on the sidewalls of the second spacer 306-7 and the bottom surface of the opening 304-7. The first part 304-3 of the bit line contact BC may then be deposited to fill the opening 304-7, surrounded by the first liner 306-5. In some embodiments, after the formation of the first spacer 306-3′, the second spacer 306-7, the first liner 306-5, and the first part 304-3 of the bit line contact BC, a planarization process is conducted to remove portions of the first spacer 306-3′, the second spacer 306-7, the first liner 306-5, and the first part 304-3 of the bit line contact BC over the top surface 303T of the second insulating film 303, providing a substantially flat surface for subsequent processing steps.

In some embodiments, the first spacer 306-3′ may be formed of doped oxide, and the second spacer 306-7 may be formed of silicon nitride. In some embodiments, the first liner 306-5 may be formed of, for example, titanium, titanium nitride, titanium silicon nitride, tantalum, tantalum nitride, tantalum silicon nitride, or a combination thereof. In some embodiments, the first part 304-3 of the bit line contact BC may be formed of tungsten.

With reference to FIG. 49, an air gap 306-3 may be formed at place AG, which the first spacer 306-3′ previously occupied, as shown in FIG. 48. In some embodiments, a thermal process, such as heat treatment, may be performed to remove the first spacer 306-3′ therefrom to create the air gap 306-3 surrounding the first part 304-3 of the bit line contact BC.

With reference to FIG. 50, the capacitor contact 403, the contact plug 411, the barrier layer 412, and the fourth insulating film 307 may be formed. Features of the capacitor contact 403, the contact plug 411, the barrier layer 412, and the fourth insulating film 307 are same as those illustrated above, and repeated descriptions are omitted.

With reference to FIG. 51, a bit line contact opening 313 may be formed in the third insulating film 305, and a bit line trench 311 may be formed in the fourth insulating film 307. In some embodiments, after a first photolithography process is performed, a first etching process, such as an anisotropic dry etch process, may be performed to form the bit line trench 311 in the fourth insulating film 307. Similarly, after a second photolithography process is performed, a second etching process, such as an anisotropic dry etch process, may be performed to form the bit line contact opening 313 in the third insulating film 305. In some embodiments, a cleaning process using a reducing agent may optionally be performed to remove defects on the top surface 304-3T of the bit line contact 304-3, which is formed of tungsten. The reducing agent may be titanium tetrachloride, tantalum tetrachloride, or a combination thereof.

A width of a bottom opening of the bit line contact opening 313 may be less than a width of a top opening of the bit line contact opening 313; in other words, a profile of the bit line contact opening 313 may be tapered from top to bottom. This means that sidewalls of the bit line contact opening 313 may be slanted away from each other. The width of the bottom opening of the bit line contact opening 313 may be approximately equal to a width of a top surface of the first part 304-3 of the bit line contact BC. The top surface of the first part 304-3 of the bit line contact BC may be exposed through the bit line contact opening 313 and the bit line trench 311.

With reference to FIG. 52, a conductive material 304-1′, such as doped polysilicon, metal, metal nitride, or metal silicide, may be deposited into the bit line trench 311 and the bit line contact opening 313 through a metallization process, while a second part 304-5 of the bit line contact BC is formed in the third insulating film 305 simultaneously. In addition, a liner 306-9′ may be formed on and attached to sidewalls of the bit line trench 311, a portion of a bottom of the bit line trench 311, the sidewalls of the bit line contact opening 313, and the bottom of the bit line contact opening 313 before the deposition of the conductive material 304-1′.

With reference to FIG. 53, subsequently, following an etch-back process, as shown in FIG. 37, a bit line 304-1 may be formed in the fourth insulating film 307. In addition, a second liner 306-9 may be formed on the sidewalls of the bit line 304-1, a portion of the bottom of the bit line 304-1, and the sidewalls and bottom of the second part 304-5 of the bit line contact BC.

One aspect of the present disclosure provides a semiconductor structure including a substrate with an active area; a plurality of first dielectric structures arranged within the substrate, wherein the active area is positioned between the first dielectric structures; and a plurality of word lines disposed in the active area and surrounded by a first insulating film over the substrate. Each of the word lines comprises a word line channel film inwardly positioned in the first insulating film and the substrate, a word line electrode disposed over and surrounded by the word line channel film, and a word line insulating film conformally disposed between the word line channel film and the word line electrode. The word line channel film includes a lower portion penetrating an upper portion of the substrate, and an upper portion positioned in the first insulating film above a top surface of the substrate.

Another aspect of the present disclosure provides a semiconductor structure including a substrate with an active area; a plurality of first dielectric structures arranged within the substrate, wherein the active area is positioned between the first dielectric structures; a first insulating film disposed over the substrate and the first dielectric structures; a second insulating film disposed over the first insulating film; a third insulating film disposed over the second insulating film; and a bit line contact comprising a first part positioned over a top surface of the substrate and a second part positioned over the first part. The first part is located within the first and second insulating films. The second part is located within the third insulating film.

Another aspect of the present disclosure provides a method for manufacturing a semiconductor structure. The method includes the steps of: providing a substrate; forming an active area in the substrate; forming a plurality of first dielectric structures arranged within the substrate, wherein the active area is positioned between the first dielectric structures; forming a first insulating film over the substrate and in contact with the active area and the first dielectric structures; forming a trench in the first insulating film and the substrate; forming a plurality of word lines in the active area and the first insulating film; forming a bit line contact over the substrate; forming an air gap surrounding the bit line contact; and forming a capacitor contact over and in contact with the active area.

Another aspect of the present disclosure provides a method for manufacturing a semiconductor structure. The method includes the steps of: providing a substrate including an active area; forming a plurality of first dielectric structures arranged within the substrate, wherein the active area is positioned between the first dielectric structures; forming a first insulating film in contact with the active area and the first dielectric structures; forming a plurality of trenches in the first insulating film and in the active area; respectively forming a plurality of word lines in the trenches; forming a second insulating film over the first insulating film; forming a neck portion of a capacitor contact and a first part of a bit line contact over the substrate and in the first and second insulating films; forming a third insulating film over the second insulating film; forming a head portion of the capacitor contact over the neck portion and in the third insulating film; forming a fourth insulating film over the third insulating film; forming a contact plug over and in contact with the head portion of the capacitor contact; forming a second part of the bit line contact; and forming a bit line over the second part of the bit line contact.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor structure, comprising:
a substrate including an active area;
a plurality of first dielectric structures arranged within the substrate, wherein the active area is positioned between the first dielectric structures; and
a plurality of word lines disposed in the active area and surrounded by a first insulating film over the substrate, wherein each of the word lines comprises:
a word line channel film inwardly positioned in the first insulating film and the substrate, wherein a lower portion of the word line channel film penetrates an upper portion of the substrate, and an upper portion of the word line channel film is positioned in the first insulating film above a top surface of the substrate;
a word line electrode disposed over and surrounded by the word line channel film; and
a word line insulating film conformally disposed between the word line channel film and the word line electrode.

2. The semiconductor structure of claim 1, further comprising:
a capacitor contact disposed over and in contact with the active area; and
a landing pad disposed over the capacitor contact, the landing pad comprising:
a contact plug disposed over and in contact with the capacitor contact;
a barrier layer attached to a sidewall of the contact plug;
a first silicide layer disposed over and in contact with the contact plug; and
a second silicide layer disposed over the contact plug and the barrier layer, in contact with a sidewall of the barrier layer,
wherein a height of the second silicide layer is greater than a height of the first silicide layer.

3. The semiconductor structure of claim 1, wherein the first insulating film is in contact with the active area and the first dielectric structures.

4. The semiconductor structure of claim 1, wherein a top surface of the word line channel film may be even with a top surface of the first insulating film.

5. The semiconductor structure of claim 1, wherein the word line channel film includes a U-shaped cross-sectional profile.

6. The semiconductor structure of claim 1, wherein the word line channel film is formed of polysilicon, the word line insulating film is formed of materials with a dielectric constant of about 4.0 or greater, and the word line electrode is formed of polysilicon, silicon germanium, metal, metal alloy, metal silicide, metal nitride, metal carbide, or a combination including multilayers thereof.

7. The semiconductor structure of claim 2, further comprising:
a second insulating film disposed over the first insulating film; and
a third insulating film disposed over the second insulating film.

8. The semiconductor structure of claim 7, wherein the capacitor contact comprises:
a neck portion in contact with the active area, the first insulating film, and the second insulting film; and
a head portion over the neck portion and in contact with the third insulating film.

9. The semiconductor structure of claim 8, wherein a width of the head portion is greater than a width of the neck portion.

10. The semiconductor structure of claim 9, wherein the head portion has a curved sidewall.

11. A semiconductor structure, comprising:
a substrate including an active area;
a plurality of first dielectric structures arranged within the substrate, wherein the active area is positioned between the first dielectric structures;
a first insulating film disposed over the substrate and the first dielectric structures;
a second insulating film disposed over the first insulating film;
a third insulating film disposed over the second insulating film; and
a bit line contact comprising a first part positioned over a top surface of the substrate, and a second part positioned over the first part, wherein the first part is located within the first and second insulating films, while the second part is located within the third insulating film.

12. The semiconductor structure of claim 11, wherein a top surface of the first part of the bit line contact is coplanar with a top surface of the second insulating film.

13. The semiconductor structure of claim 12, wherein a bottom surface of the first part of the bit line contact is positioned higher than a bottom surface of the first insulating film.

14. The semiconductor structure of claim 11, further comprising:
an air gap surrounding the first part of the bit line contact;
a spacer positioned between the air gap and the first part of the bit line contact; and
a first liner conformally disposed on the first part of the bit line contact, positioned between the spacer and the bit line contact, as well as between the bit line contact and the substrate.

15. The semiconductor structure of claim 11, wherein the first part and the second part are separated by a second liner.

16. The semiconductor structure of claim 11, further comprising a plurality of word lines disposed in the active area and surrounded by the first insulating film, wherein each of the word lines comprises:
a word line channel film inwardly positioned in the first insulating film and the substrate, wherein a lower portion of the word line channel film penetrates an upper portion of the substrate, and an upper portion of the word line channel film is positioned in the first insulating film above a top surface of the substrate;
a word line electrode disposed over and surrounded by the word line channel film; and
a word line insulating film conformally disposed between the word line channel film and the word line electrode.

17. The semiconductor structure of claim 16, wherein the word line channel film includes a U-shaped cross-sectional profile.

18. The semiconductor structure of claim 11, further comprising:
a capacitor contact disposed over and in contact with the active area; and
a landing pad disposed over the capacitor contact, the landing pad comprising:
a contact plug disposed over and in contact with the capacitor contact;
a barrier layer attached to a sidewall of the contact plug;
a first silicide layer disposed over and in contact with the contact plug; and
a second silicide layer disposed over the contact plug and the barrier layer, in contact with a sidewall of the barrier layer,
wherein a height of the second silicide layer is greater than a height of the first silicide layer.

19. The semiconductor structure of claim 18, wherein the capacitor contact comprises:
a neck portion in contact with the active area, the first insulating film, and the second insulting film; and
a head portion over the neck portion and in contact with the third insulating film.

20. The semiconductor structure of claim 19, wherein the head portion has a curved sidewall.
